(19) United States
(12) Patent Application Publication
(10) Pub. No.: US 2026/0068414 A1
(43) Pub. Date: Mar. 5, 2026

(54) PHOTOELECTRIC DEVICE MODULE AND OPERATION METHOD THEREOF

(71) Applicant: Raynergy Tek Incorporation, HSINCHU (TW)

(72) Inventors: Yi-Ming CHANG, HSINCHU (TW); Ping-Yen CHEN, HSINCHU (TW); Wei-Hsiang LIN, HSINCHU (TW); Chung-Wei HSU, HSINCHU (TW)

(21) Appl. No.: 18/966,153

(22) Filed: Dec. 3, 2024

(30) Foreign Application Priority Data
Aug. 28, 2024 (TW) 113132426

(51) Int. Cl. H10K 39/32

(52) U.S. Cl. CPC H10K 39/32

(57) ABSTRACT

The present disclosure provides a photoelectric device module including a first electrode, a photoactive layer, and a circuit module. The first electrode is opaque. The photoactive layer is disposed on the first electrode. The circuit module is disposed on the photoactive layer, in which the circuit module includes a semiconductor substrate and a second electrode, and the second electrode is disposed between the photoactive layer and the semiconductor substrate. The semiconductor substrate has a transmittance of less than 1% for light having a wavelength of less than 1000 nm and a transmittance of more than 10% for light having a wavelength of 1050 nm to 5500 nm.

### CROSS-REFERENCE TO RELATED APPLICATION

This application claims priority to Taiwan Application Serial Number 113132426, filed Aug. 28, 2024, which is herein incorporated by reference.

### BACKGROUND

### Field of Invention

The present disclosure relates to a photoelectric device module and an operation method thereof.

### Description of Related Art

Photoelectric sensors are electronic components that convert light sources into electrical signals and can be categorized into photodiodes, photoresistors, or phototransistors. Under the irradiation of light with different intensities, the photodiodes can generate corresponding current response to achieve the effect of sensing light intensity and can rectify the current. In order to improve the performance (e.g., photoelectric conversion efficiency, sensitivity, and spectral response) of the photodiodes and reduce the cost of the photodiodes, many new materials that can be applied to photodiodes have been developed. However, these materials may be susceptible to damage during the manufacturing process. For example, high temperatures in the process of manufacturing filters may damage these materials.

### SUMMARY

The present disclosure provides a photoelectric device module including a first electrode, a photoactive layer, and a circuit module. The first electrode is opaque. The photoactive layer is disposed on the first electrode. The circuit module is disposed on the photoactive layer, in which the circuit module includes a semiconductor substrate and a second electrode, and the second electrode is disposed between the photoactive layer and the semiconductor substrate. The semiconductor substrate has a transmittance of less than 1% for light having a wavelength of less than 1000 nm and a transmittance of more than 10% for light having a wavelength of 1050 nm to 5500 nm.

In some embodiments, a material of the semiconductor substrate includes silicon.

In some embodiments, a material of the first electrode includes silver, gold, aluminum, copper, molybdenum, titanium, tungsten, titanium nitride, carbon material, or combinations thereof.

In some embodiments, the photoelectric device module further includes an encapsulation layer, in which the encapsulation layer is opaque and covers a side surface and a bottom surface of the first electrode and a side surface of the photoactive layer.

In some embodiments, the second electrode is light-transmissive.

In some embodiments, the circuit module further includes a conductive wire, and the conductive wire is embedded in the semiconductor substrate and is electrically connected to the second electrode. A portion of the conductive wire overlapping the second electrode has a first area in top view, the second electrode has a second area in top view, and the first area is smaller than the second area.

In some embodiments, the photoelectric device module further includes a first carrier transport layer and a second carrier transport layer. The first carrier transport layer is disposed between the first electrode and the photoactive layer. The second carrier transport layer is disposed between the photoactive layer and the circuit module.

In some embodiments, the circuit module further includes a light-transmissive insulating layer, the light-transmissive insulating layer is disposed between the photoactive layer and the semiconductor substrate, and the second electrode is embedded in the light-transmissive insulating layer.

The present disclosure provides a method of operating a photoelectric device module, and it includes receiving light by the photoelectric device module of any of the foregoing embodiments, in which an upper surface of the circuit module is a light receiving surface.

The present disclosure provides a photoelectric device module including a circuit module including a first semiconductor substrate and a first electrode, a photoactive layer, a second electrode, and a second semiconductor substrate. The photoactive layer is disposed on the circuit module, in which the first electrode is disposed between the first semiconductor substrate and the photoactive layer. The second electrode is disposed on the photoactive layer, and the second electrode is light-transmissive. The second semiconductor substrate is disposed on the second electrode. The second semiconductor substrate has a transmittance of less than 1% for light having a wavelength of less than 1000 nm and a transmittance of more than 10% for light having a wavelength of 1050 nm to 5500 nm.

In some embodiments, the photoactive layer includes a first photoactive layer and a second photoactive layer that are stacked, and the first photoactive layer and the second photoactive layer are in direct contact with each other to form a bonding interface.

In some embodiments, the photoelectric device module further includes a third electrode, in which the third electrode is disposed between the photoactive layer and the second electrode.

In some embodiments, the photoelectric device module further includes a first carrier transport layer and a second carrier transport layer. The first carrier transport layer is disposed between the circuit module and the photoactive layer. The second carrier transport layer is disposed between the photoactive layer and the second electrode.

In some embodiments, a material of the second semiconductor substrate includes silicon.

In some embodiments, the second electrode includes a transparent conductive oxide (TCO), a transparent conductive polymer, silver nanowires, a metal-containing layer with a thickness of less than or equal to 15 nm, or combinations thereof.

The present disclosure provides a method of operating a photoelectric device module, and it includes receiving light by the photoelectric device module of any of the foregoing embodiments, in which the photoelectric device module has a light receiving surface, and the light receiving surface is an upper surface, a lower surface, or a combination of the photoelectric device module.

### BRIEF DESCRIPTION OF THE DRAWINGS

The present disclosure can be more fully understood by reading the following detailed description of the embodiments, with reference made to the accompanying drawings.

FIG. 1A and FIG. 1B are cross-sectional schematic views of photoelectric device modules according to various embodiments of the present disclosure.

FIG. 2 is a top schematic view of a conductive wire and a second electrode according to various embodiments of the present disclosure.

FIG. 3 is a flowchart of a manufacturing method of a photoelectric device module according to various embodiments of the present disclosure.

FIG. 4 shows a cross-sectional schematic view of intermediate stages of manufacturing a photoelectric device module according to various embodiments of the present disclosure.

FIG. 5 is a cross-sectional schematic view of a photoelectric device module according to various embodiments of the present disclosure.

FIG. 6 to FIG. 11 show cross-sectional schematic views of intermediate stages of manufacturing photoelectric device modules according to various embodiments of the present disclosure, respectively.

FIG. 12 and FIG. 15 are cross-sectional schematic views of photoelectric device modules of Comparative Example 1 and Example 1, respectively.

FIG. 13 shows absorption spectra of the P-type organic semiconductor and the N-type organic semiconductor of the photoactive layer of Comparative Example 1.

FIG. 14 and FIG. 16 are external quantum efficiency-wavelength diagrams of photoelectric device modules of Comparative Example 1 and Example 1, respectively.

FIG. 17 and FIG. 19 are cross-sectional schematic views of photoelectric device modules of Comparative Example 2 and Example 2, respectively.

FIG. 18 and FIG. 20 are external quantum efficiency-wavelength diagrams of photoelectric device modules of Comparative Example 2 and Example 2, respectively.

### DETAILED DESCRIPTION

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present disclosure.

Although a series of operations or steps are used below to describe the method disclosed herein, an order of these operations or steps should not be construed as a limitation to the present disclosure. For example, some operations or steps may be performed in a different order, and/or other steps may be performed at the same time. In addition, it is not necessary to perform all of the operations, steps, and/or features shown to achieve the embodiments of the present disclosure. In addition, each operation or step described herein may contain several sub-steps or actions.

The present disclosure provides a photoelectric device module and an operation method thereof. The photoelectric device module may utilize a semiconductor substrate as a filter for the photoelectric device module. The semiconductor substrate does not allow visible light to penetrate but allows short-wave infrared (SWIR) light to penetrate, so it can prevent interference with the signal detection of the photoelectric device module. The semiconductor substrate is connected to the photoelectric conversion module of the photoelectric device module by a bonding operation, and there is no need to dispose other filters in the photoelectric device module, thus preventing that the manufacturing process (e.g., deposition process) of the filters affects the property of the photoelectric device module. The photoelectric device module of the present disclosure may have excellent photoelectric characteristics and a thin and simple structure and can reduce manufacturing costs, and may be applied to, for example, advanced driver assistance system (ADAS), defect detection, or machine vision.

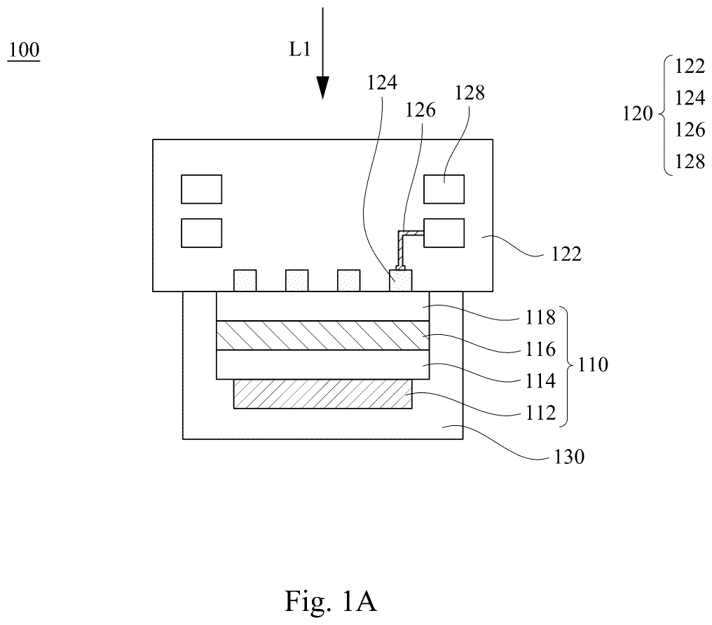

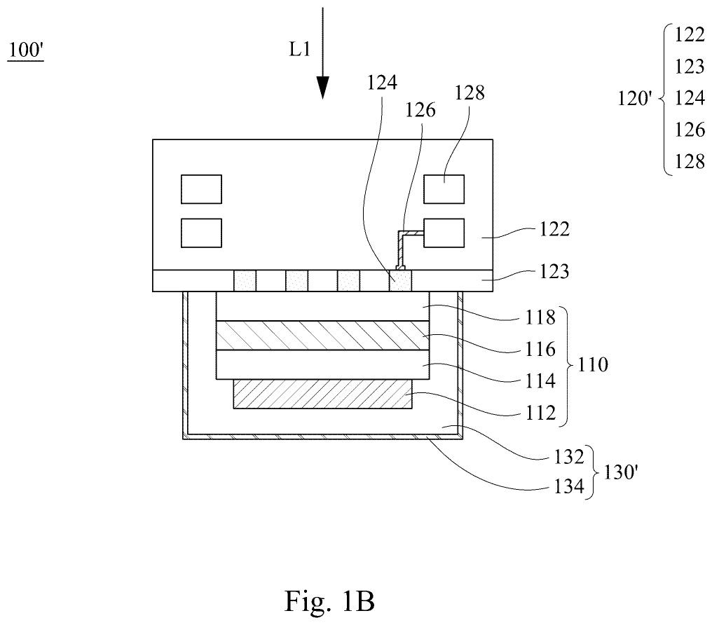

The present disclosure provides a photoelectric device module. FIG. 1A is a cross-sectional schematic view of a photoelectric device module 100 according to various embodiments of the present disclosure. The photoelectric device module 100 includes a photoelectric conversion module 110 and a circuit module 120 that are bonded. The photoelectric conversion module 110 includes a first electrode 112, a first carrier transport layer 114, a photoactive layer 116, and a second carrier transport layer 118. The first carrier transport layer 114 is disposed on the first electrode 112. The photoactive layer 116 is disposed on the first carrier transport layer 114. The second carrier transport layer 118 is disposed on the photoactive layer 116. The circuit module 120 is disposed on the second carrier transport layer 118. The circuit module 120 includes a semiconductor substrate 122 and second electrodes 124, and the second electrodes 124 are spaced apart and are disposed between the second carrier transport layer 118 and the semiconductor substrate 122. In some embodiments, the circuit module 120 further includes a conductive wire 126 and a readout circuit (ROIC) 128, which can receive signals generated by the photoelectric conversion module 110, and the conductive wire 126 is embedded in the semiconductor substrate 122 and is electrically connected to the second electrode 124 and the readout circuit 128. The readout circuit 128 may include a thin-film transistor (TFT). For simplifying the drawing, only one conductive wire 126 is shown in FIG. 1A, but each of the second electrodes 124 in FIG. 1A can be electrically connected to the corresponding readout circuit 128 by a corresponding conductive wire. The number of the second electrodes 124 is not limited by FIG. 1A, and the number of second electrodes 124 can be adjusted arbitrarily according to the design needs. The photoelectric device module 100 can be used as a light-sensitive element or an image-sensitive element. FIG. 1B is a cross-sectional schematic view of a photoelectric device module 100′ according to various embodiments of the present disclosure. The difference between the photoelectric device module 100′ and the photoelectric device module 100 is that the circuit module 120′ of the photoelectric device module 100′ includes a light-sensitive element. The difference between the photoelectric device module 100′ and the photoelectric device module 100 is that the circuit module 120′ of the photoelectric device module 100′ further includes a light-transmissive insulating layer 123, the light-transmissive insulating layer 123 is disposed between the photoactive layer 116 and the semiconductor substrate 122, and the second electrodes 124 are embedded in the light-transmissive insulating layer 123. The light-transmissive insulating layer 123 can prevent leakage currents and undesired conduction. The light-transmissive insulating layer 123 allows the penetration of light having a wavelength from 1000 nm to 5500 nm. In some embodiments, the light-transmissive insulating layer 123 includes silicon nitride, silicon dioxide, poly(p-xylylene), epoxy resin, polyethylene terephthalate, poly (methyl methacrylate), polycarbonate, polyimide, or combinations thereof.

Please refer to FIG. 1A again. The circuit module 120 of the photoelectric device module 100 of the present disclosure has a self-filtering characteristic. In more detail, the semiconductor substrate 122 does not allow visible light to penetrate but allows short-wave infrared (SWIR) light to penetrate. The semiconductor substrate 122 can be used as a filter for light with a wavelength of less than 1000 nm to filter out unwanted light to prevent interference with the signal detection. In more detail, the semiconductor substrate 122 has a transmittance of less than 1% for light having a wavelength less than 1000 nm and a transmittance of more than 10% for light having a wavelength of 1050 nm to 5500 nm, such as 1050, 1500, 2000, 2500, 3000, 3500, 4000, 4500, or 5000 nm. Thus, the photoelectric device module 100 of the present disclosure can respond to SWIR light and be free from visible light interference during detection. The present disclosure provides a method of operating the photoelectric device module 100, which includes receiving light L1 by the photoelectric device module 100, in which the upper surface of the circuit module 120 is a light receiving surface. In other words, the upper surface of the semiconductor substrate 122 is the light receiving surface. The photoelectric device module 100 can be applied in the field of SWIR sensors. The light L1 is irradiated to the photoelectric device module 100 from above, and in some embodiments, the photoelectric device module 100 does not have a filter, a filter film, a filter structure, or combinations thereof disposed between the first electrode 112 and the encapsulation layer 130.

In the process of manufacturing a general filter, a coating process or an deposition process is usually used to produce a filter, a filter film, or a filter structure; however, the filter, the filter film, or the filter structure usually requires a high-temperature condition and a long process time to be formed, which may damage the components or materials in the photoelectric device module. The photoelectric device module 100 of the present disclosure uses the semiconductor substrate 122 as a filter directly, and there is no need to perform an additional process to form a filter, a filter film, and/or a filter structure, thus preventing the problem of high-temperature damage mentioned above. Therefore, the photoelectric device module 100 of the present disclosure can have good performance and a thin, light, and simplified structure, and can also reduce manufacturing costs. In addition, the semiconductor substrate 122 may have better water-blocking and gas-blocking characteristics than a general filter, and thus may be used as part of the packaging structure of the photoelectric device module 100. In some embodiments, a material of the semiconductor substrate 122 includes silicon. In some embodiments, the semiconductor substrate 122 is a silicon substrate or a silicon-containing composite substrate. Silicon has a lower cost compared to germanium or indium gallium arsenide, which is advantageous for reducing the manufacturing cost.

Please continue to refer to FIG. 1A. In some embodiments, the photoelectric device module 100 further includes an encapsulation layer 130, in which the encapsulation layer 130 covers the side surface and bottom surface of the photoelectric device module 100. The encapsulation layer 130 may also be referred to as a passivation layer. In more detail, the encapsulation layer 130 covers the side surfaces of the first electrode 112, the first carrier transport layer 114, the photoactive layer 116, the second carrier transport layer 118, and the bottom surface of the first electrode 112. The encapsulation layer 130 may be light-transmissive or opaque. In some embodiments, the encapsulation layer 130 is light-transmissive, and for example, the material of the encapsulation layer 130 includes silicon nitride, silicon dioxide, aluminium oxide, zirconium dioxide, poly(p-xylylene), epoxy resin, polyethylene terephthalate, poly(methyl methacrylate), polycarbonate, polyimide, glass, or combinations thereof. Please refer to FIG. 1B again. The photoelectric device module 100′ further includes an opaque encapsulation layer 130′, and the encapsulation layer 130′ includes an insulating layer 132 and a metal layer 134. In more detail, the encapsulation layer 130′ is opaque and does not allow visible light to penetrate. The insulating layer 132 covers the side and bottom surfaces of the photoelectric conversion module 110, and the metal layer 134 covers the side and bottom surfaces of the insulating layer 132. The insulating layer 132 may include silicon nitride, silicon dioxide, aluminum oxide, zirconium dioxide, poly(p-xylylene), epoxy resin, polyethylene terephthalate, poly(methyl methacrylate), polycarbonate, polyimide, glass, or combinations thereof. The metal layer 134 may include silver, gold, aluminum, copper, molybdenum, titanium, tungsten, or combinations thereof, and may be a metal foil or a metal film formed by evaporation deposition.

Please continue to refer to FIG. 1A. The upper surface of the photoelectric device module 100 is a light receiving surface, and the first electrode 112 disposed below is opaque. For example, the first electrode 112 is opaque and does not allow visible light to penetrate. For example, the first electrode 112 is a metal-containing layer with a thickness greater than 10 nm or a conductive carbon layer with a thickness greater than 50 nm. In some embodiments, the material of the first electrode 112 includes silver, gold, aluminum, copper, molybdenum, titanium, tungsten, titanium nitride, carbon material, or combinations thereof. The second electrode 124 are light-transmissive, and for example, the second electrode 124 allows visible light, near-infrared light, and/or short-wave infrared (SWIR) light to penetrate. For example, the second electrodes 124 allow light having a wavelength between 1000 nm and 5500 nm to penetrate. For example, the second electrodes 124 are transparent electrodes. In some embodiments, the second electrodes 124 include a transparent conductive oxide (TCO), a transparent conductive polymer, silver nanowires, a metal-containing layer with a thickness of less than or equal to 15 nm, or combinations thereof. The TCO includes indium zinc oxide (IZO), indium gallium oxide (IGO), indium gallium zinc oxide (IGZO), indium tin oxide (ITO), indium tin zinc oxide (ITZO), aluminum zinc oxide (AZO), or combinations thereof. The transparent conductive polymer includes poly(3,4-ethylenedioxythiophene) polystyrene sulfonate (PEDOT:PSS), polyaniline, ployfluorene, polypyrrole, polythiophene, polycarbazole, or combinations thereof. The metal-containing layer may include a metal layer with a thickness less than or equal to 15 nm, an alloy layer with a thickness less than or equal to 15 nm, or a combination thereof. The metal-containing layer may include silver, gold, aluminum, copper, titanium, molybdenum, titanium nitride, titanium tungsten, or combinations thereof.

The photoactive layer 116 includes a material that can respond to SWIR light. More specifically, the photoactive layer 116 can detect light L1 having a wavelength between 1000 nm and 5500 nm. The photoactive layer 116 can be referred to as a photoelectric conversion layer. In some embodiments, the thickness of the photoactive layer 116 is from 140 nm to 500 nm, such as 140, 150, 200, 250, 300, 350, 400, 450, or 500 nm. In some embodiments, the photoactive layer 116 includes an organic semiconductor, an inorganic semiconductor, a quantum dot, a perovskite, or combinations thereof. In some embodiments, the quantum dot includes CdSe, CdZnS, CdSeS, CdS, ZnSe, InP, InS, CdTe, CuInS₂, CuInZnS, ZnS, PbS, PbSe, AgInS₂, Ag₂Te, InAs, Cd₃AS₂, AgBiS₂, InAs/InP, InGaP, or combinations thereof. In some embodiments, the perovskite has the following formula: ABX₃, in which A is an organic cation, B is a metal cation, and X is a halogen anion. In some embodiments, the perovskite includes CH₃NH₃PbI₃, CH₃NH₃PbBr₃, (MeNH₃)PbBr₃, Cs₂Sn₃I₆, Ag₃BiI₆, (CH₃NH₃)₃Bi₂Cl₉, Cs₂SnI₅Br, Cs₂TiBr₆, or combinations thereof. In some embodiments, the organic semiconductor includes one or more P-type organic semiconductors and one or more N-type organic semiconductors. The P-type organic semiconductor may be a conjugated polymer, and the N-type organic semiconductor may be a non-fullerene material or a fullerene material. For example, the P-type organic semiconductors include:

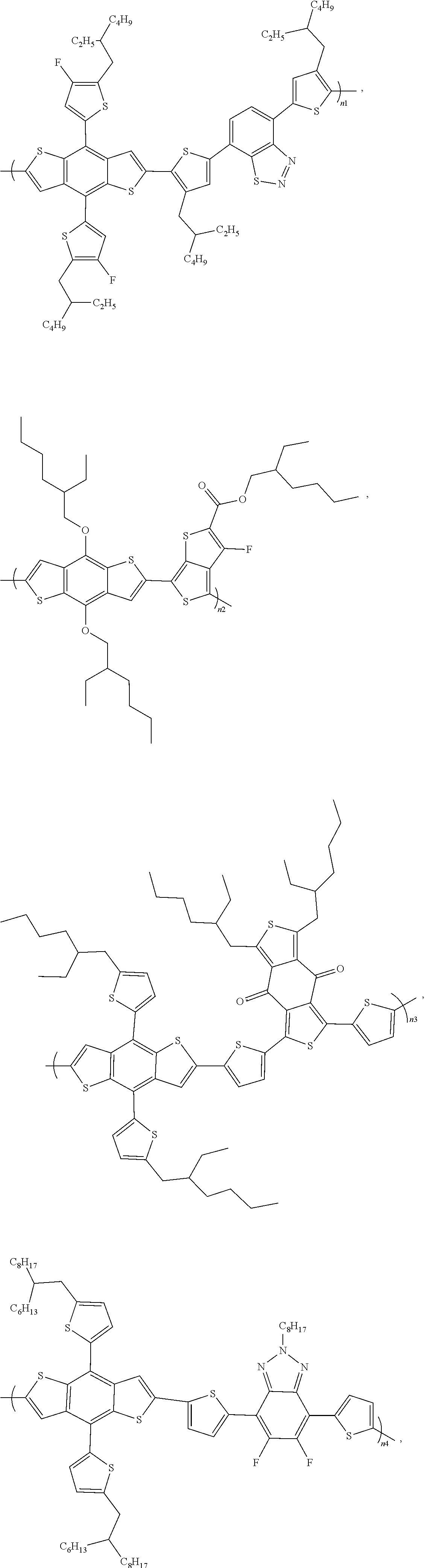

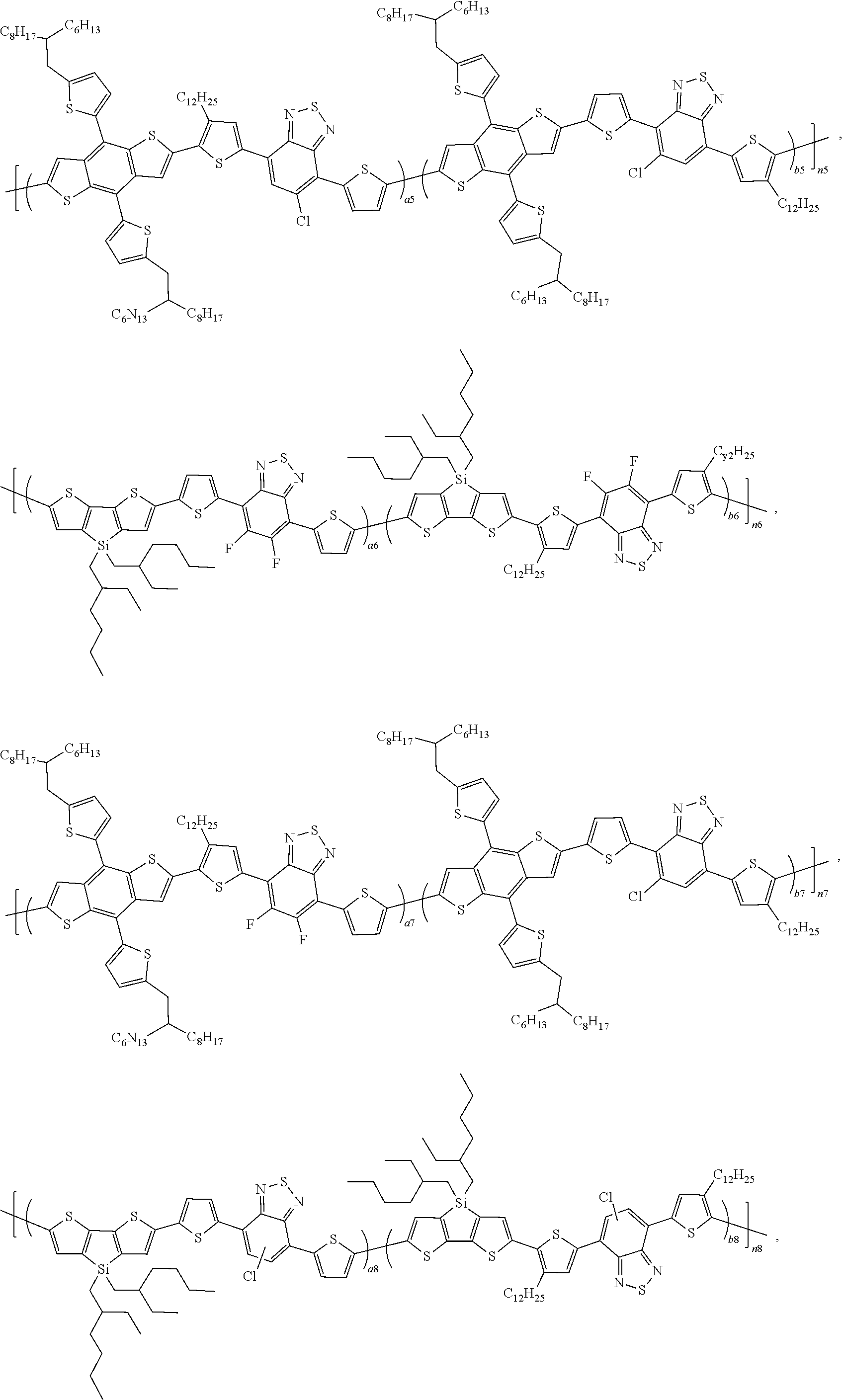

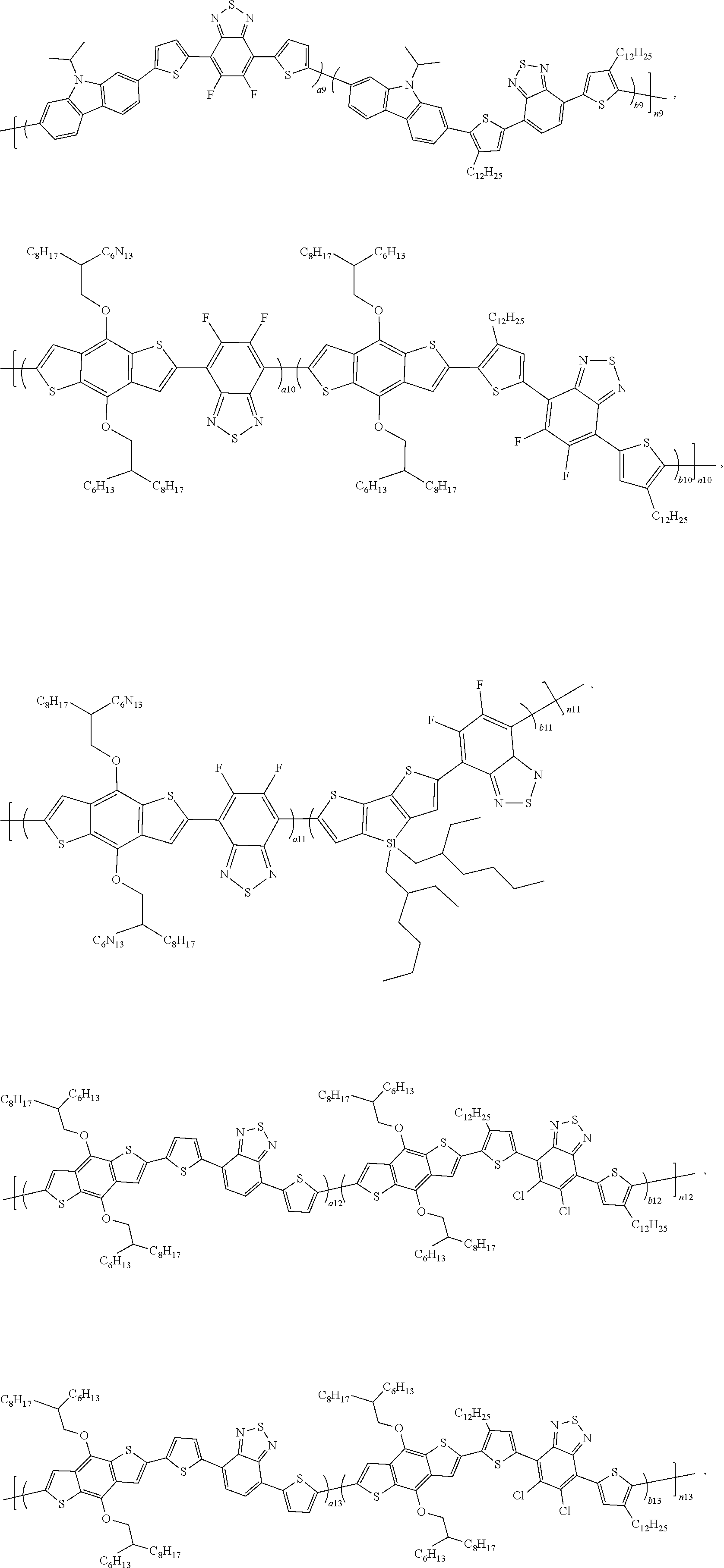

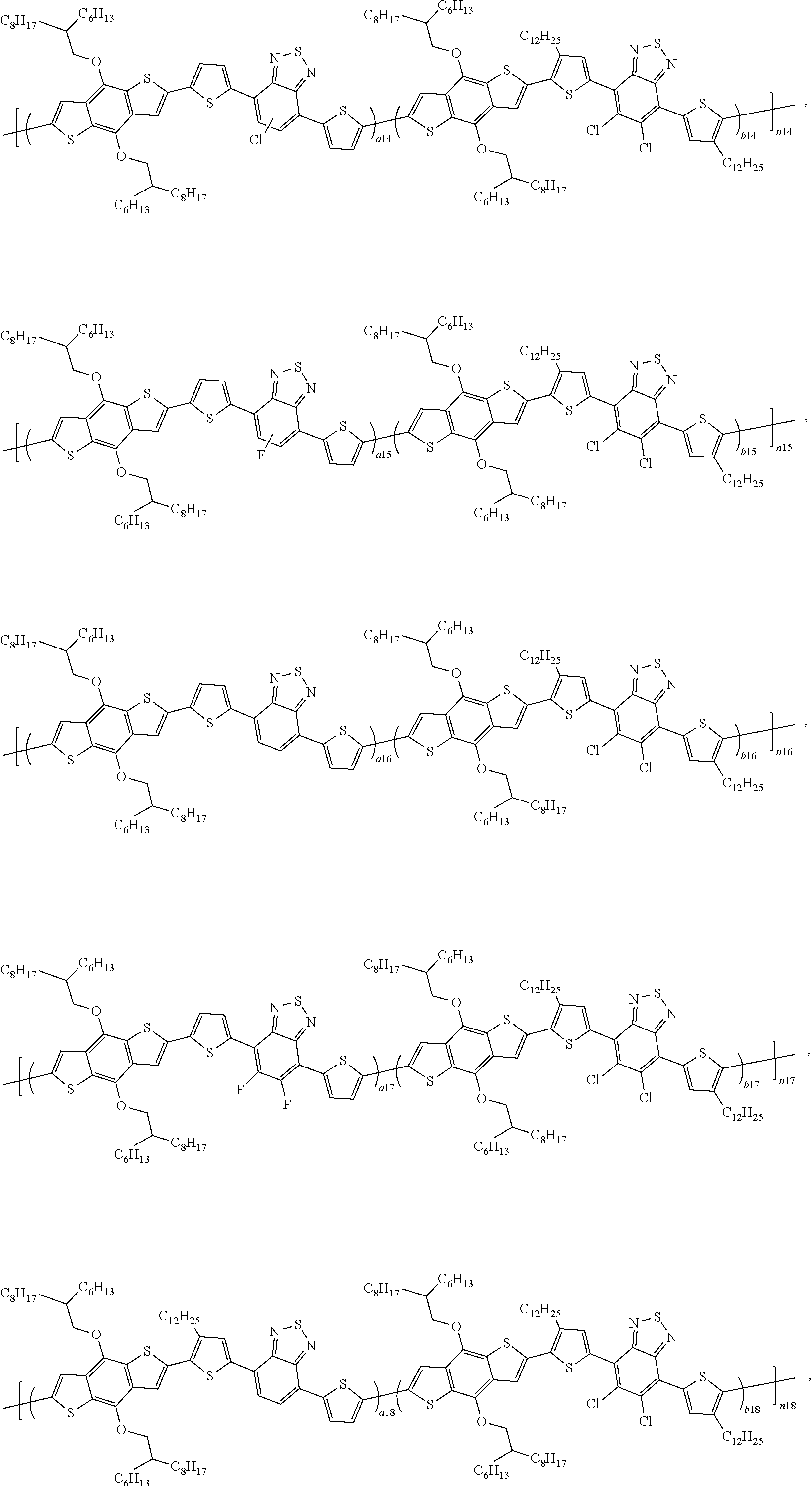

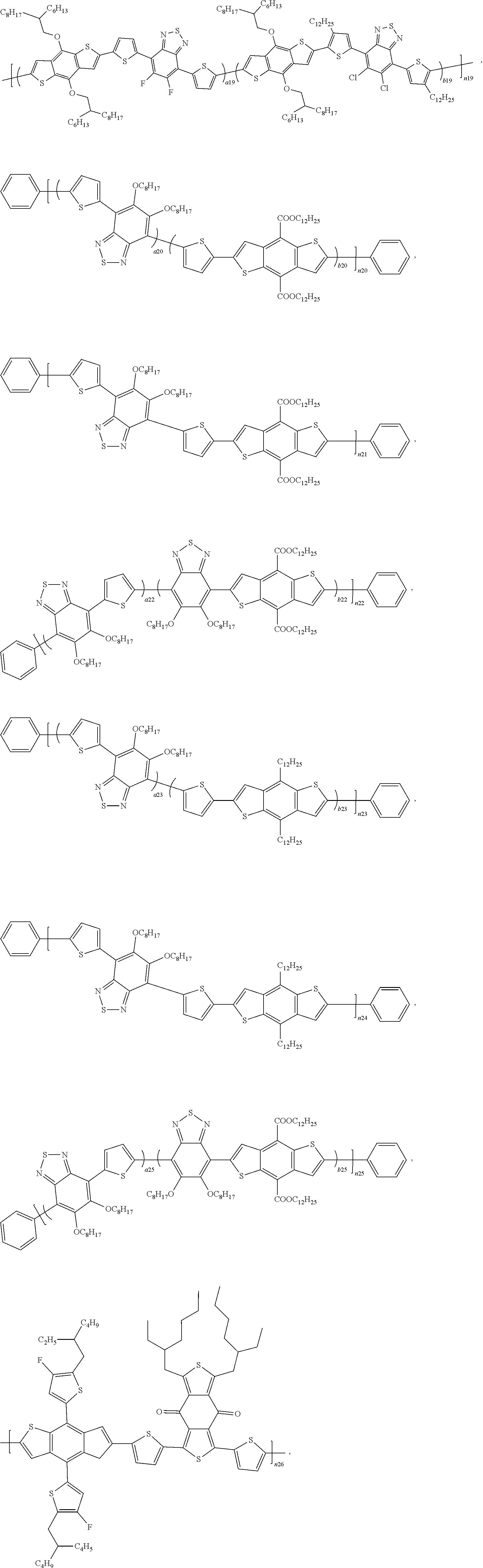

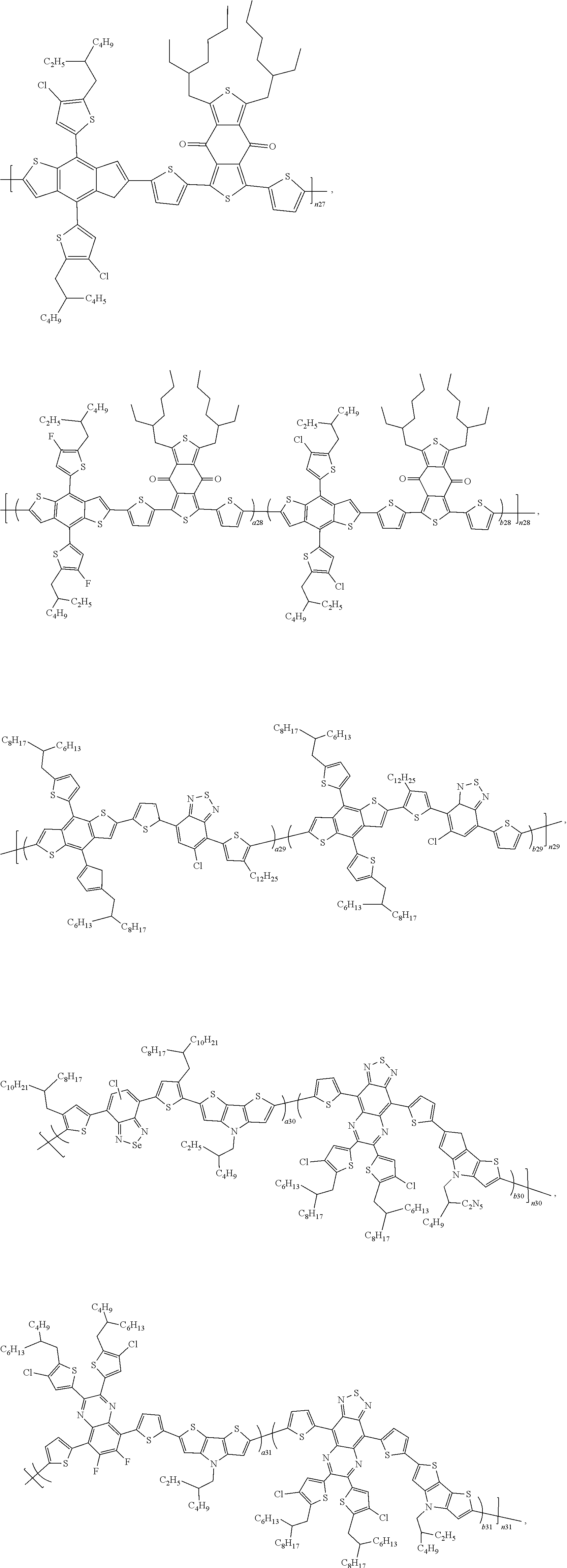

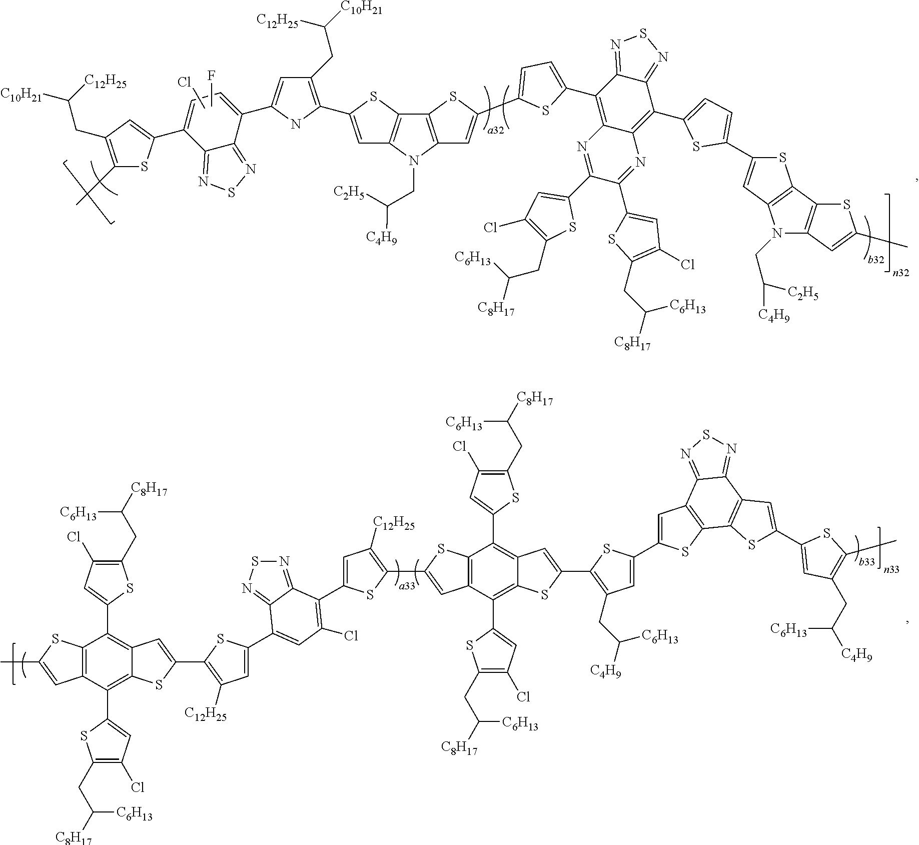

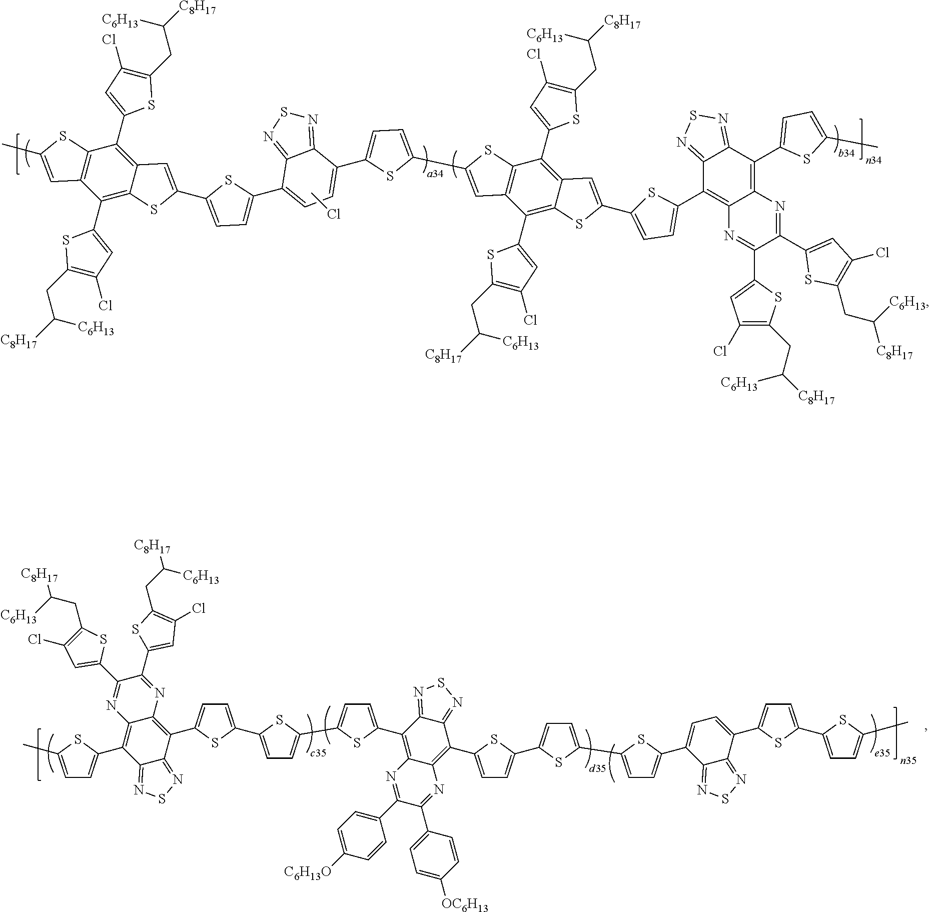

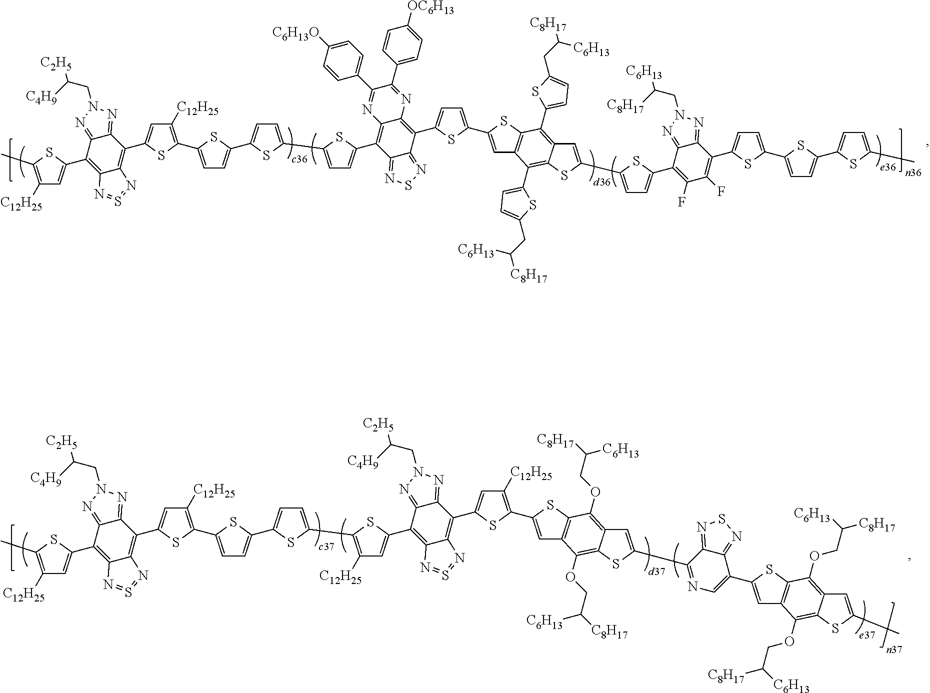

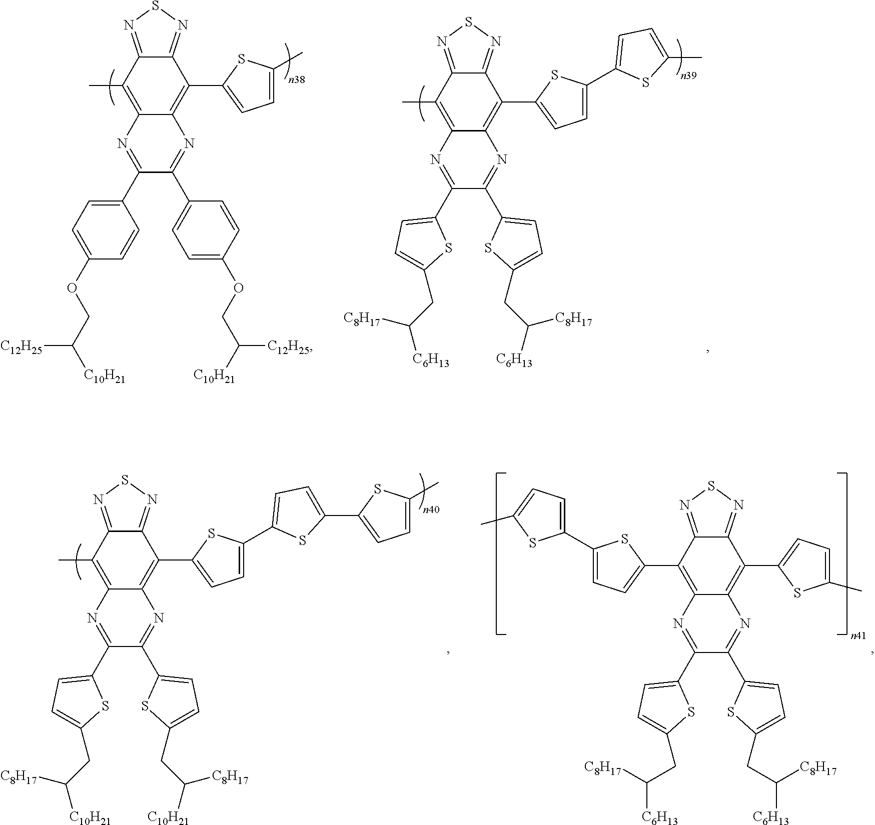

or combinations thereof. In the above P-type organic semiconductors, n1 to n41 are respectively a positive integer from 1 to 1000. a5 to a20, a22, a23, a25, a28 to a34, b5 to b20, b22, b23, b25, b28 to b34, c35 to c37, d35 to d37, and e35 to d37 respectively represent a mole fraction and are greater than 0 and less than 1. The sum of all mole fractions in each of the P-type organic semiconductors is one. For example, the N-type organic semiconductors include:

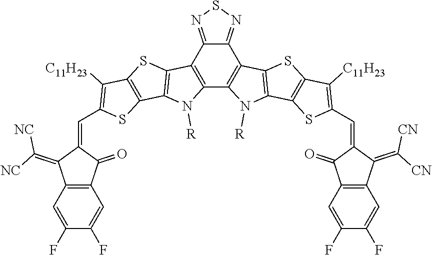

### (R is

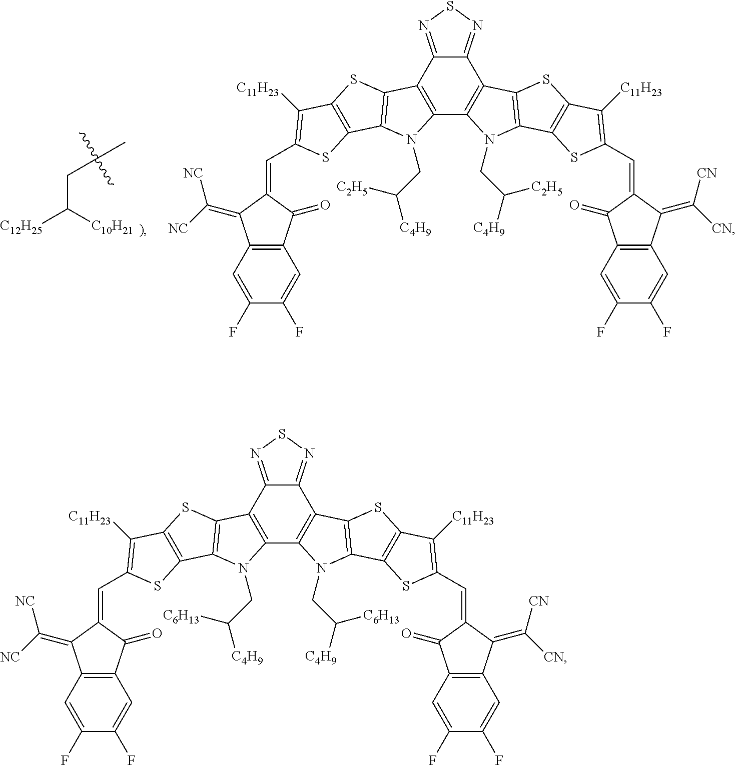

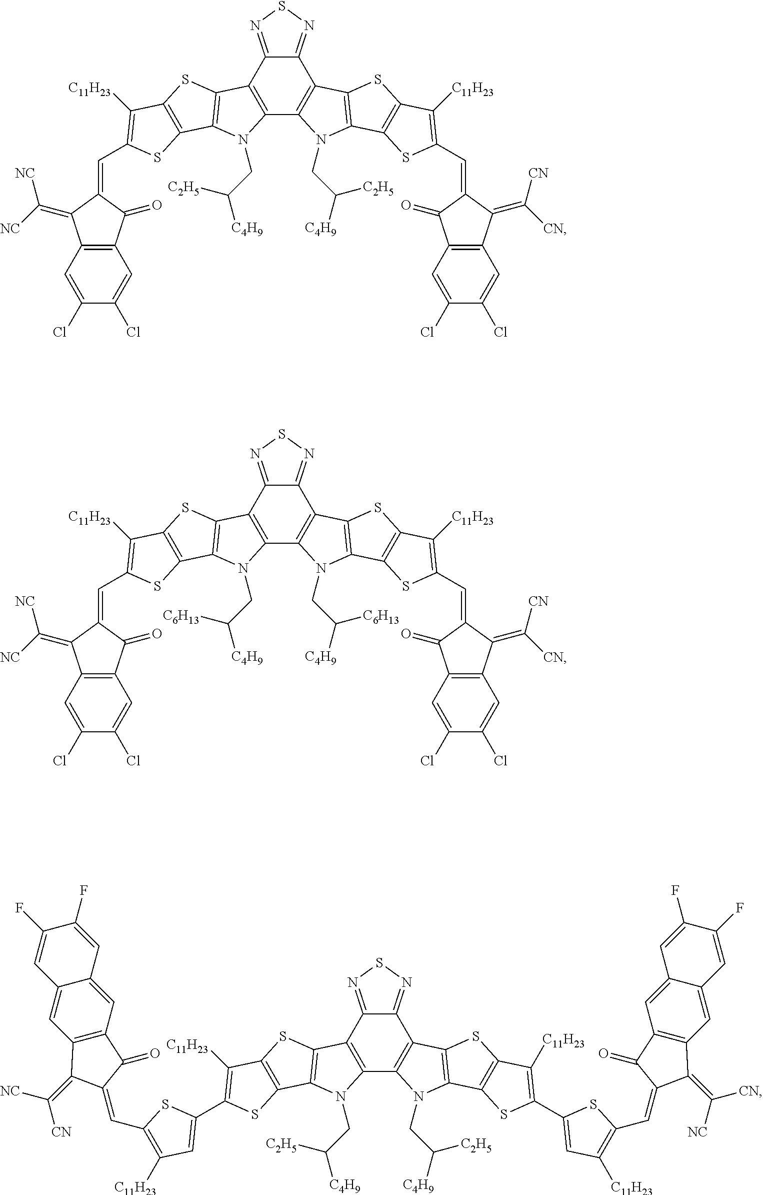

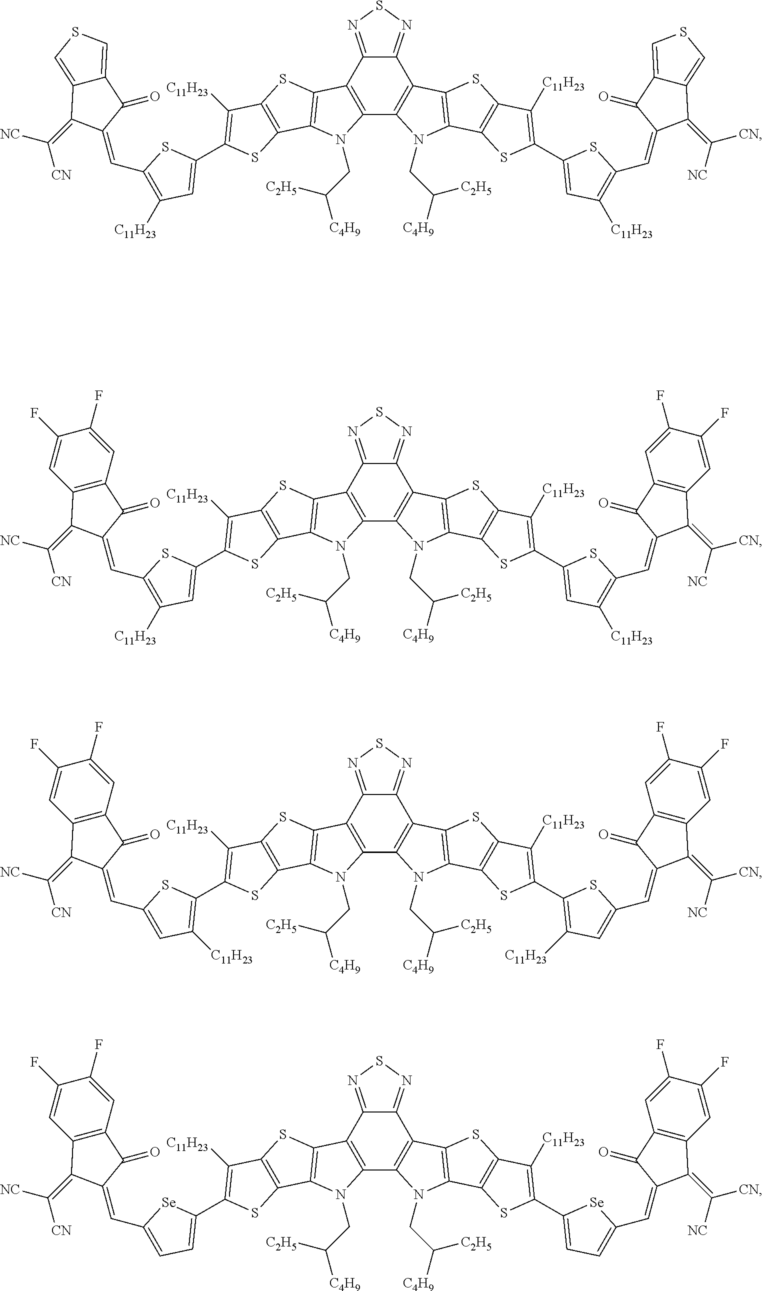

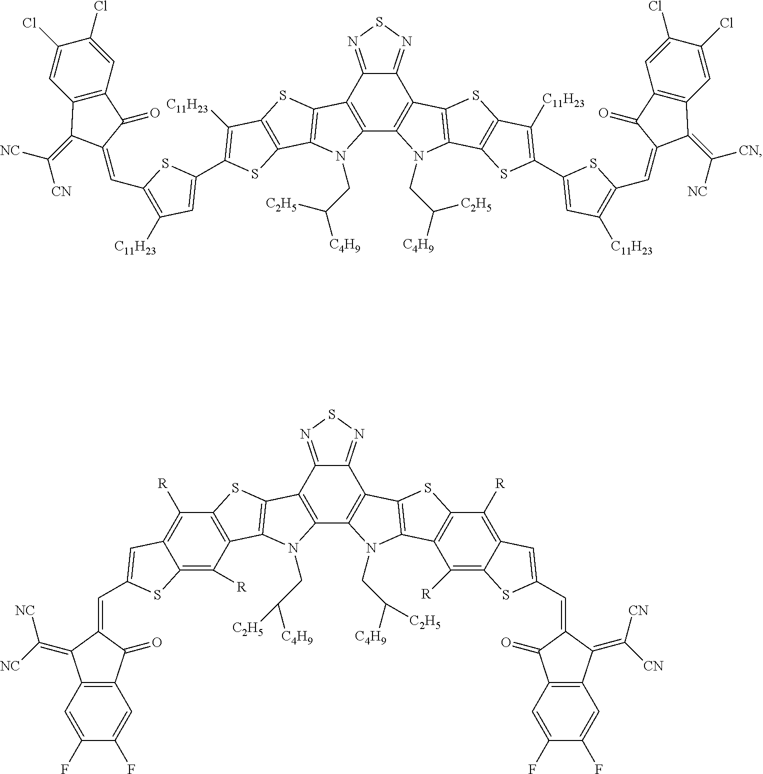

(R is an ethylhexyl),

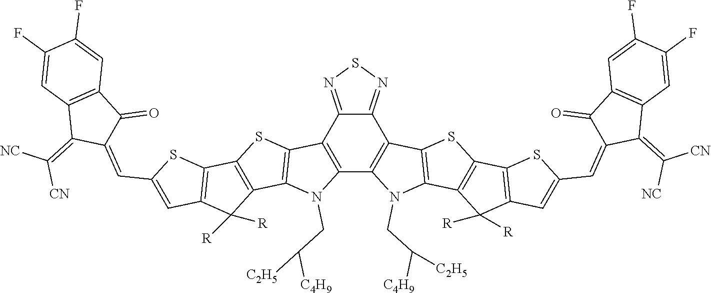

(R is an ethylhexyl),

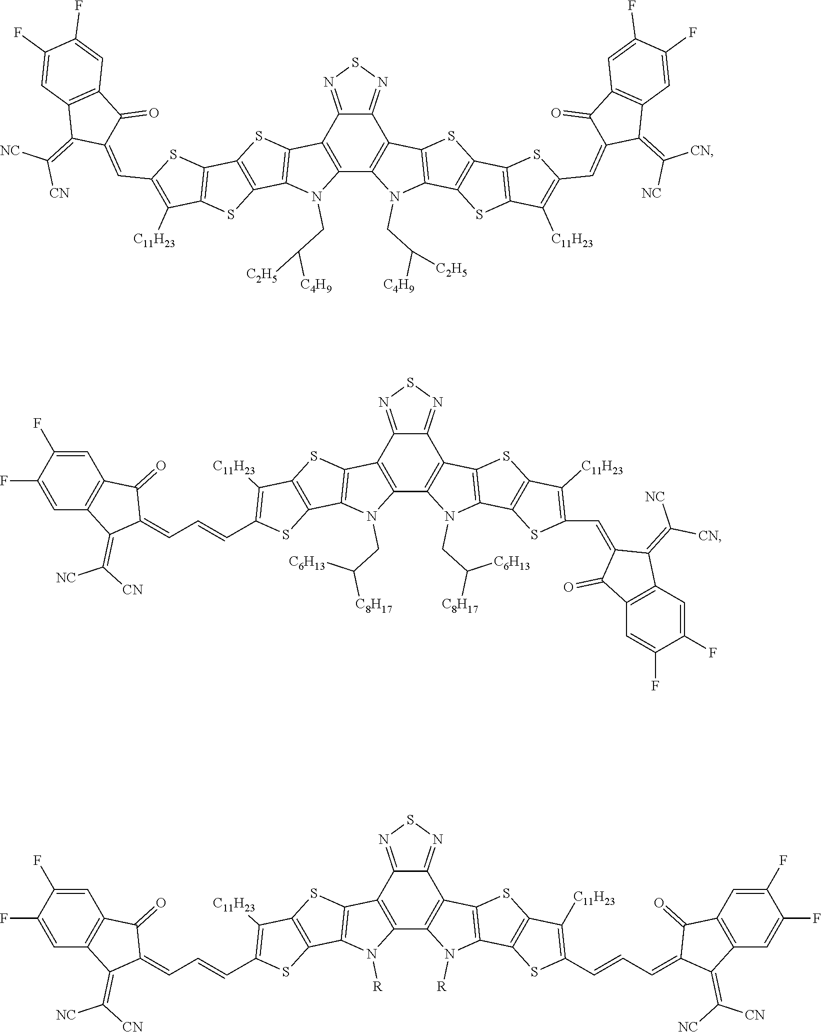

(R is a hexyldecyl),

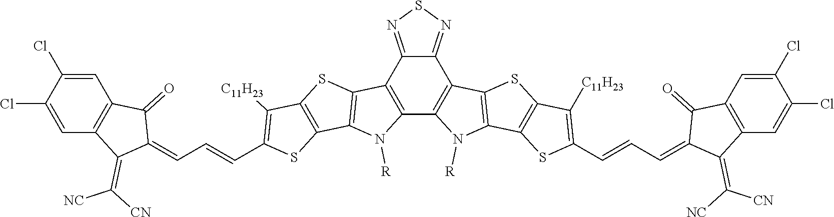

(R is a hexyldecyl),

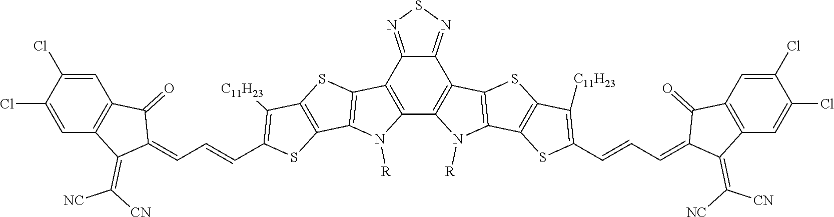

(R is a decyltetradecyl),

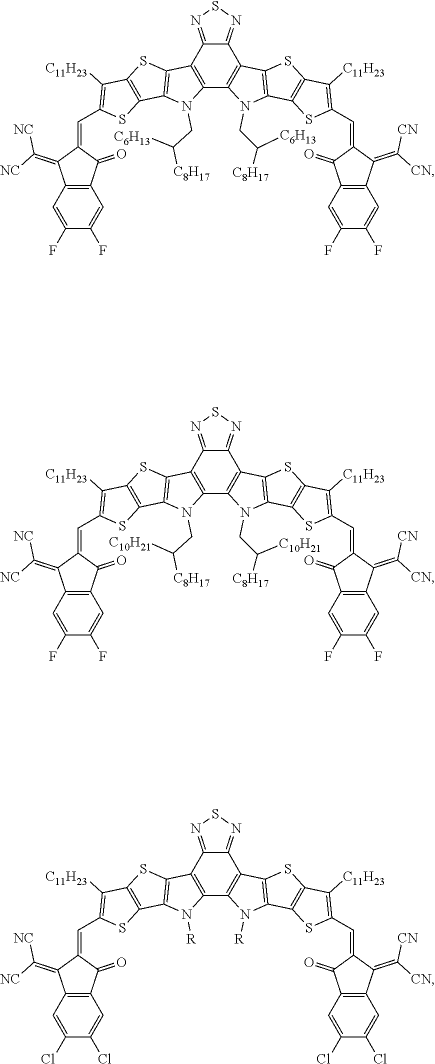

### (R is

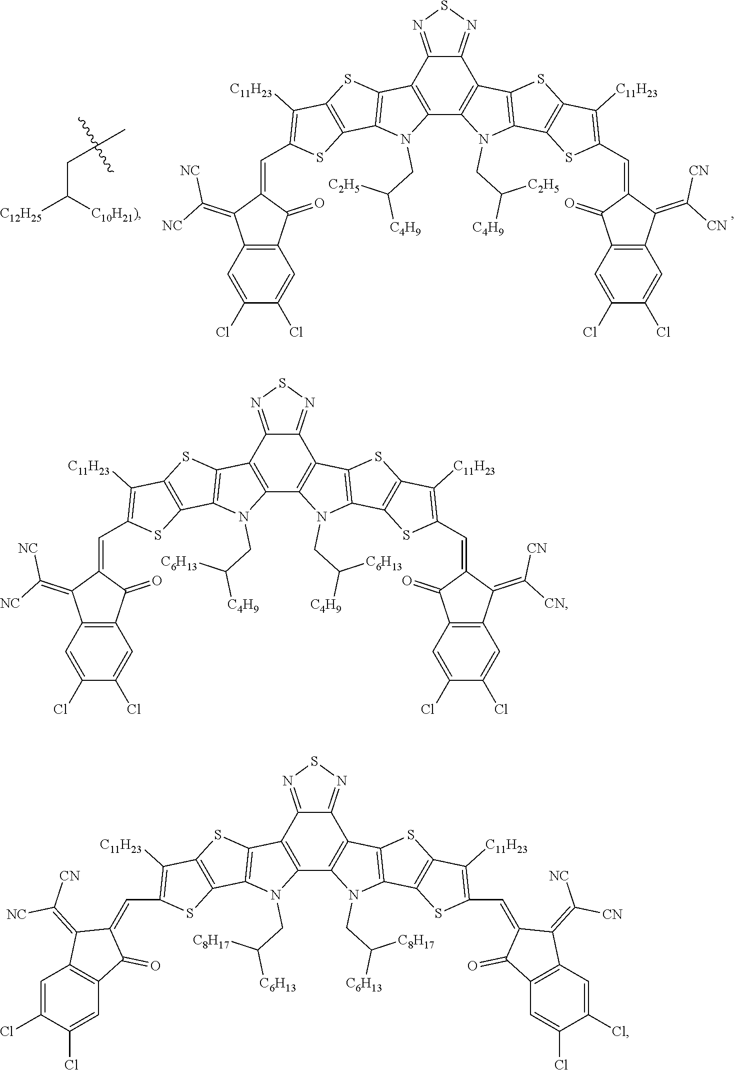

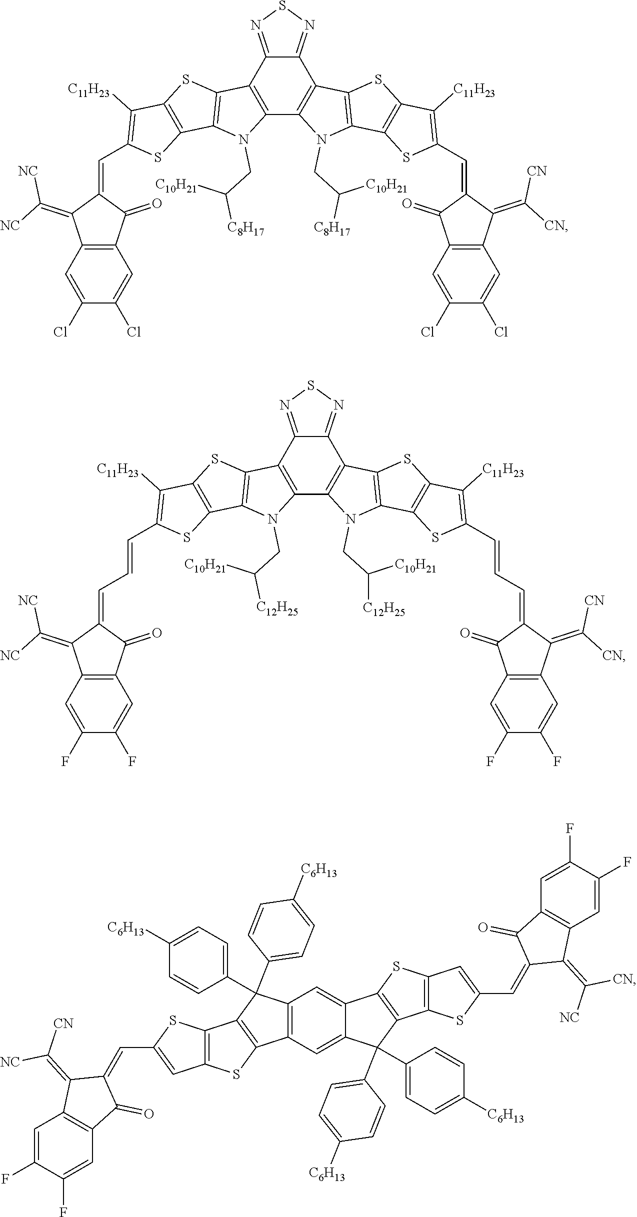

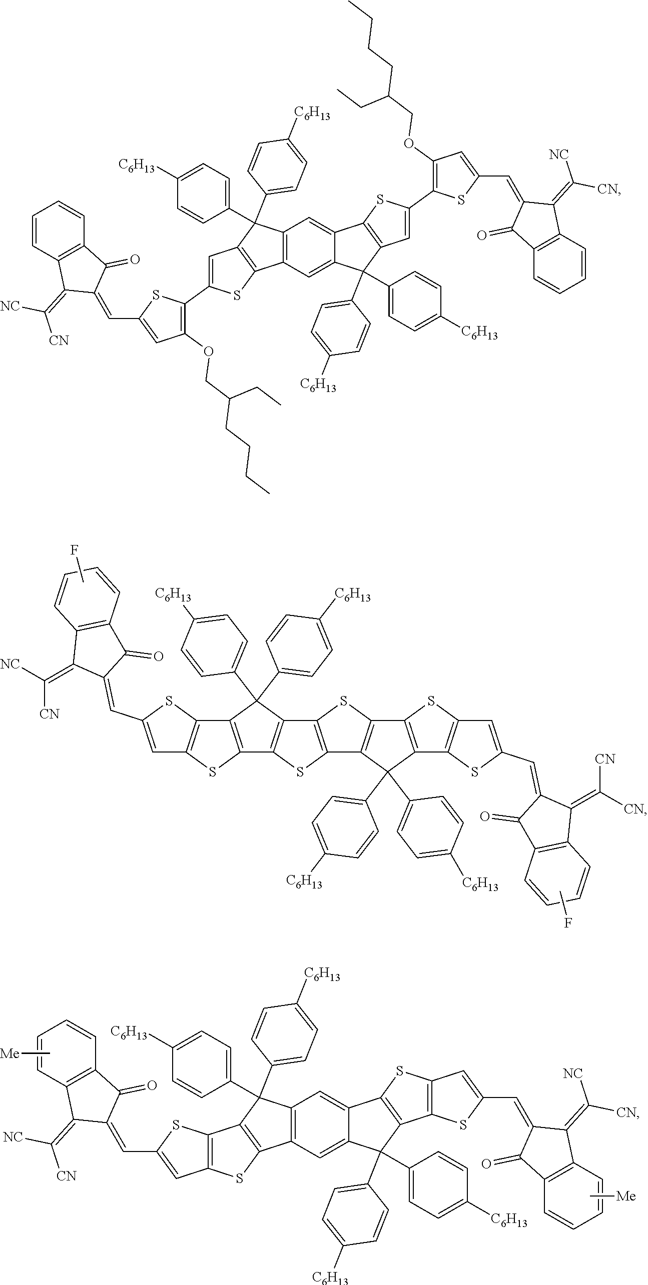

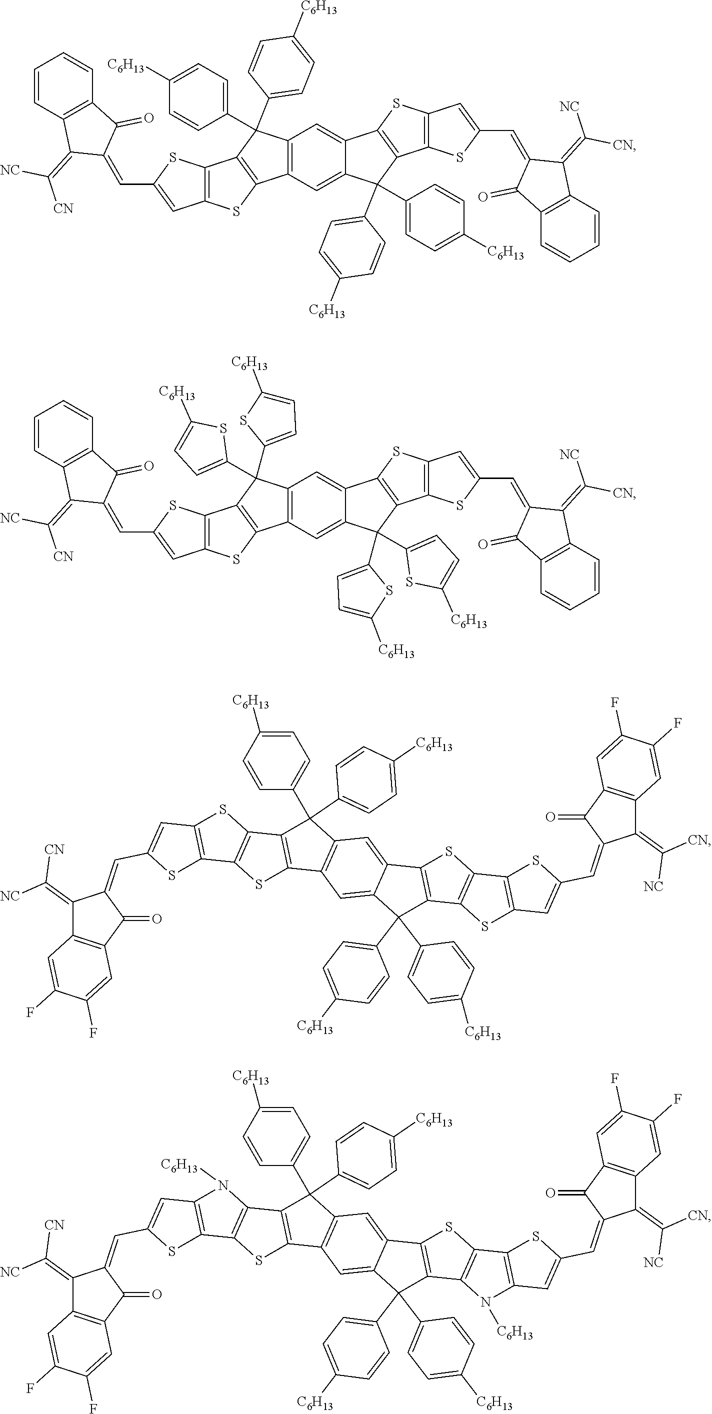

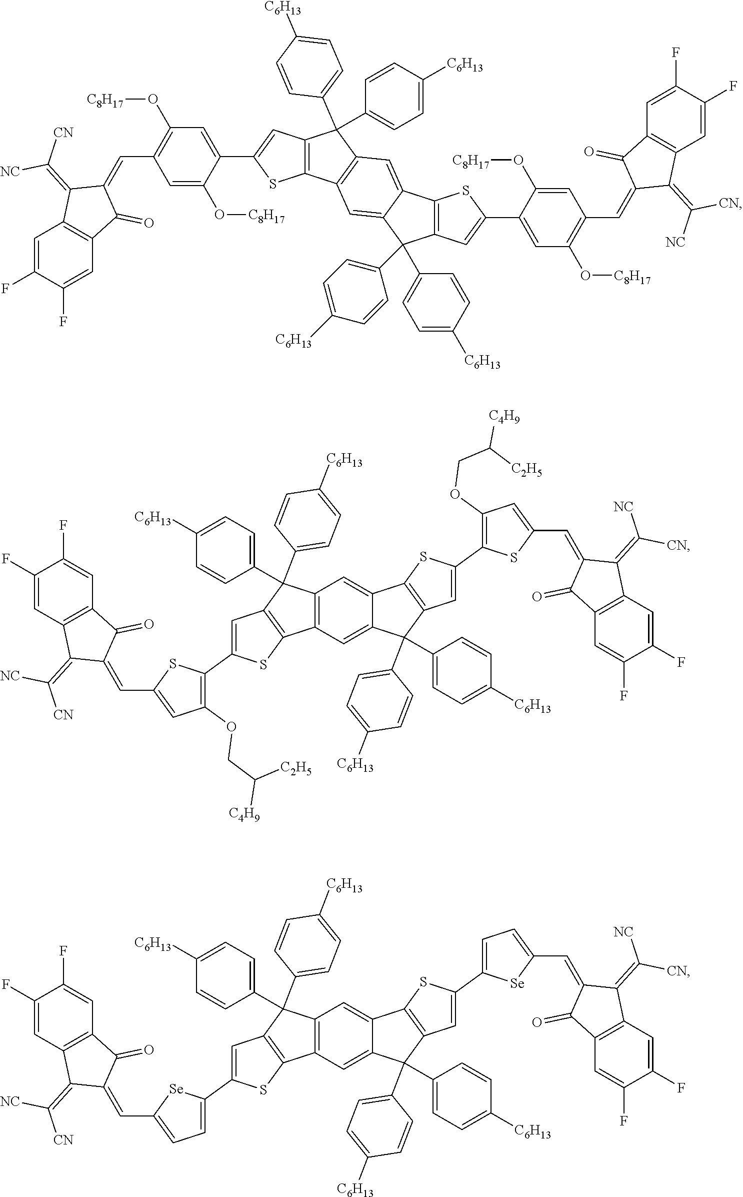

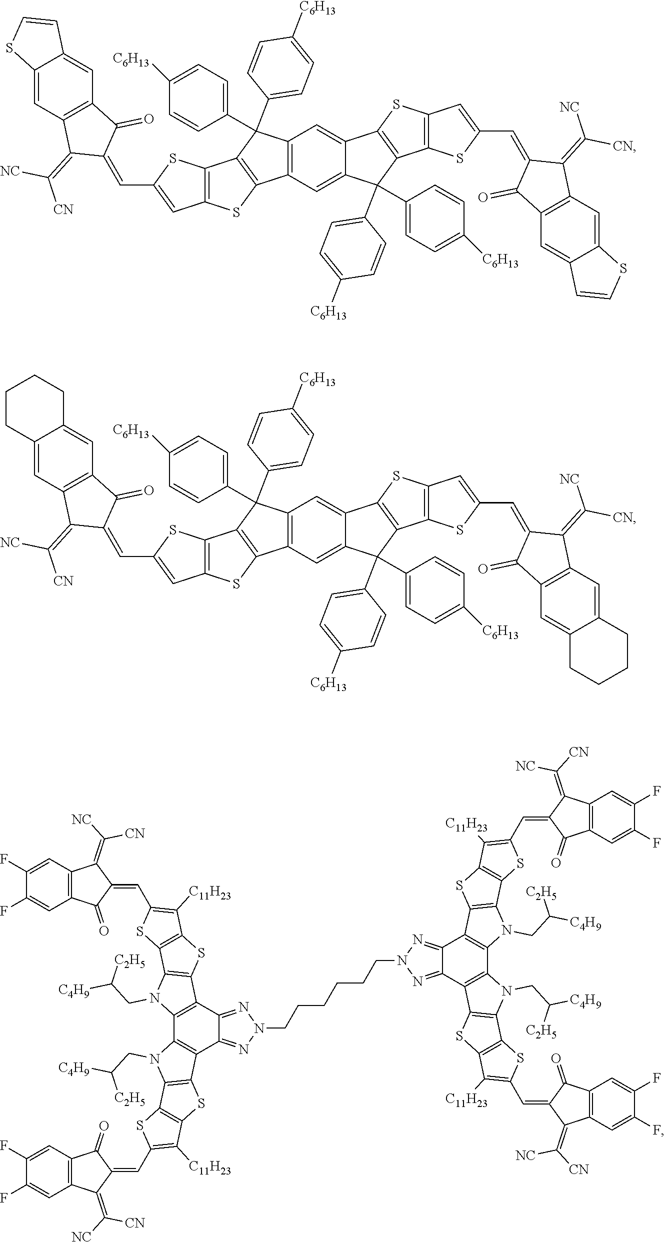

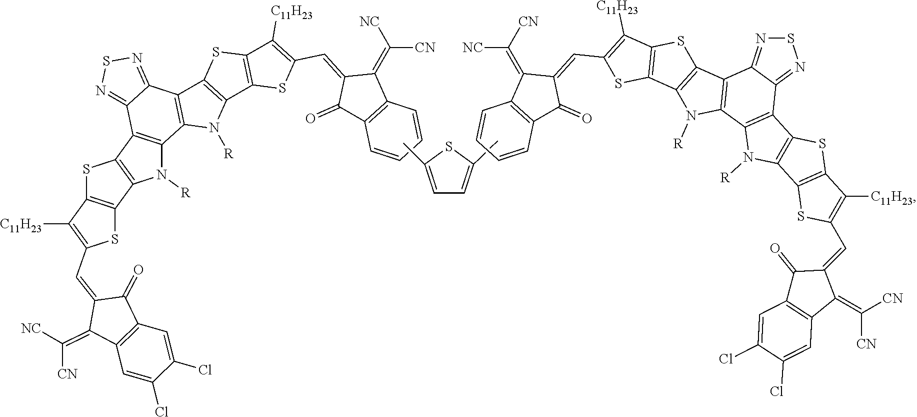

### (R is

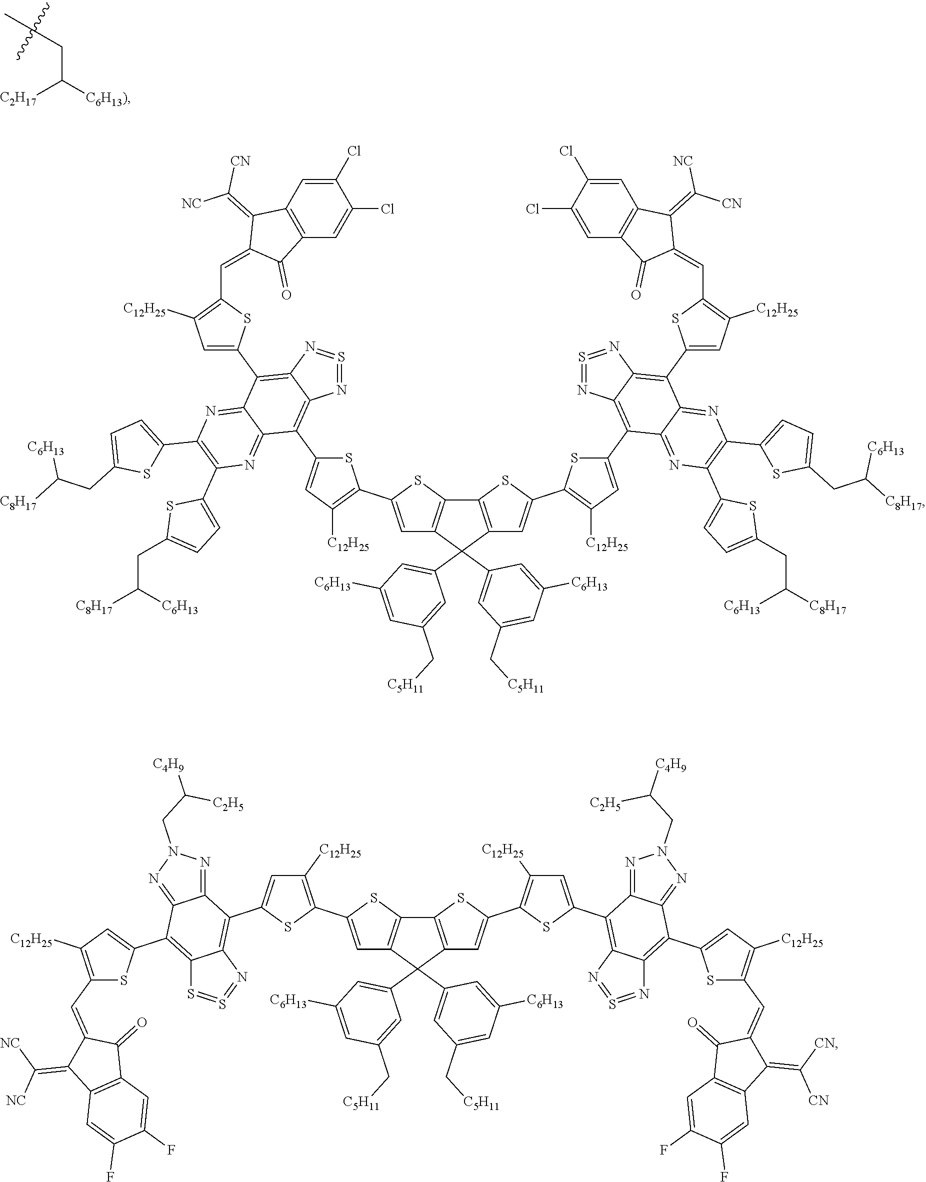

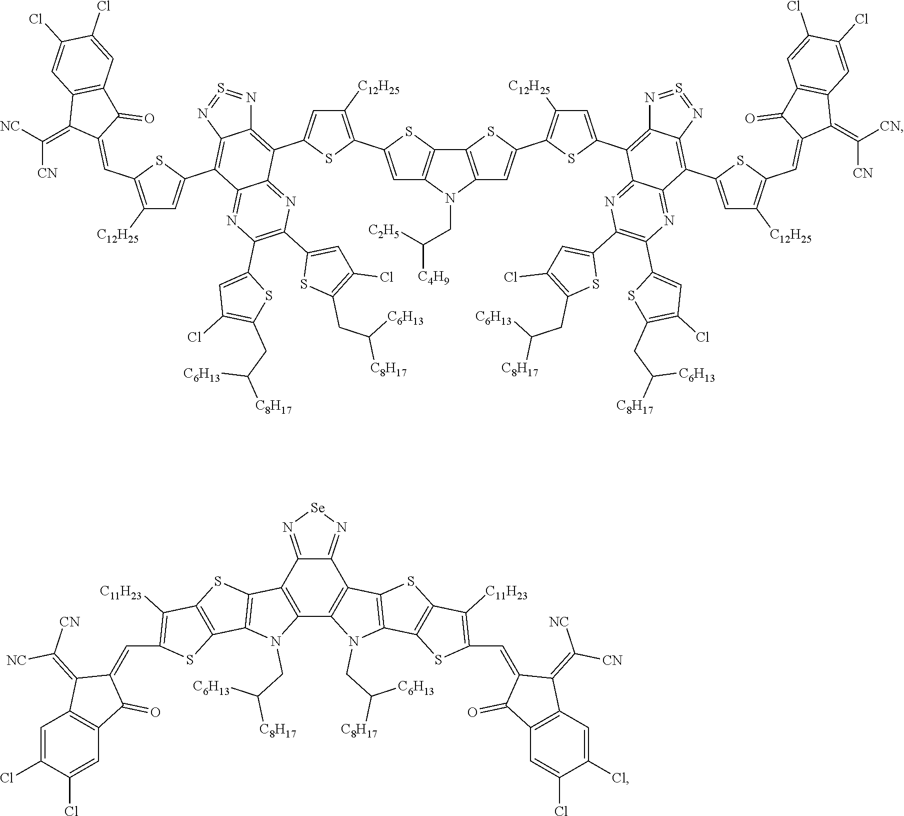

or combinations thereof.

Please continue to refer to FIG. 1A. The first carrier transport layer 114 and the second carrier transport layer 118 have different materials. In some embodiments, among the first carrier transport layer 114 and the second carrier transport layer 118, one is an electron transport layer and the other is a hole transport layer. For example, the first carrier transport layer 114 is an electron transport layer, and the second carrier transport layer 118 is a hole transport layer. For example, the first carrier transport layer 114 is a hole transport layer, and the second carrier transport layer 118 is an electron transport layer. In some embodiments, the first carrier transport layer 114 and the second carrier transport layer 118 respectively include a metal oxide or an organic material (e.g., an organic small molecule, a polymer, or a crosslinkable molecule). In some embodiments, the electron transport layer includes aluminum zinc oxide, zinc oxide, titanium oxide (e.g., titanium dioxide), tin oxide (e.g., tin dioxide), 4,7-diphenyl-1,10-phenanthroline (BPhen), or combinations thereof. In some embodiments, the hole transport layer includes molybdenum trioxide (MoOs), nickel monoxide (NiO), tungsten trioxide (WO₃), PEDOT:PSS,

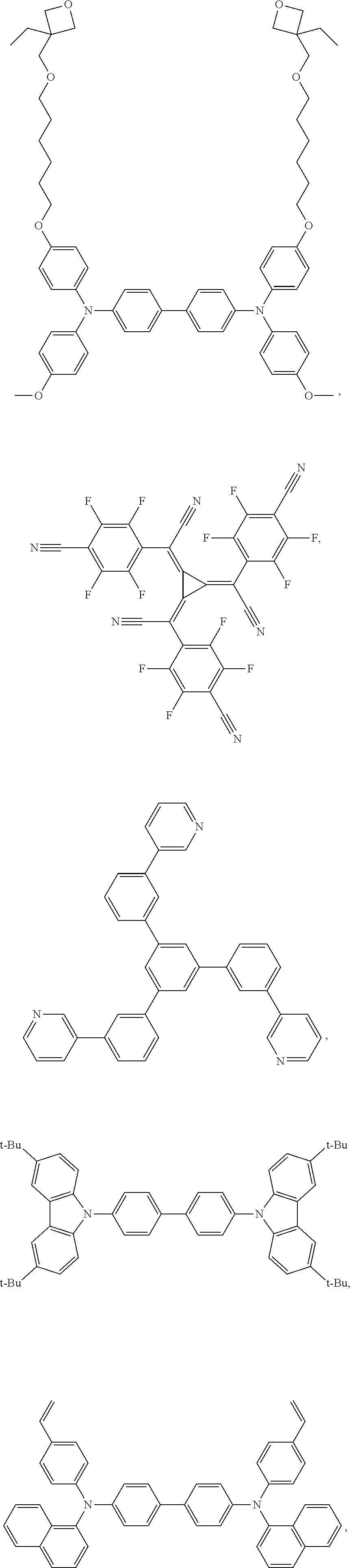 [SMILES: CCC1(COCCCCCCOc2ccc(N(c3ccc(OC)cc3)c3ccc(-c4ccc(N(c5ccc(OC)cc5)c5ccc(OCCCCCCOCC6(CC)COC6)cc5)cc4)cc3)cc2)COC1 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1cncc(-c2cccc(-c3cc(-c4cccc(-c5cccnc5)c4)cc(-c4cccc(-c5cccnc5)c4)c3)c2)c1 ; CC(C)(C)c1ccc2c(c1)c1cc(C(C)(C)C)ccc1n2-c1ccc(-c2ccc(-n3c4ccc(C(C)(C)C)cc4c4cc(C(C)(C)C)ccc43)cc2)cc1 ; C=Cc1ccc(N(c2ccc(-c3ccc(N(c4ccc(C=C)cc4)c4cccc5ccccc45)cc3)cc2)c2cccc3ccccc23)cc1]

bathocuproine (BCP), buckminsterfullerene (C60), polyethylenimine (PEI), ethoxylated polyethylenimine (PEIE), or combinations thereof. The PEI may have the following structure of

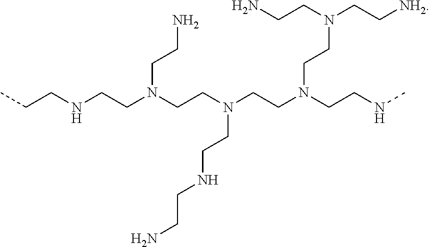

The PEIE may have the following structure of

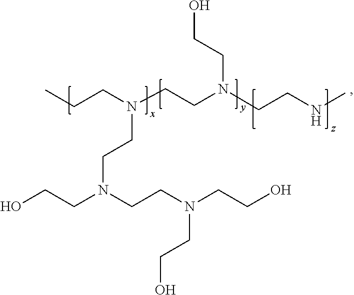

in which x, y, and z are mole fractions, and the sum of x, y, and z is 1. In other embodiments, the first carrier transport layer 114 between the first electrode 112 and the photoactive layer 116 is omitted so that the photoactive layer 116 is disposed on the first electrode 112 and directly contacts the first electrode 112. In other embodiments, the second carrier transport layer 118 between the photoactive layer 116 and the circuit module 120 is omitted so that the circuit module 120 is disposed on the photoactive layer 116 and directly contacts the photoactive layer 116, and the second electrode 124 is disposed between the photoactive layer 116 and the semiconductor substrate 122.

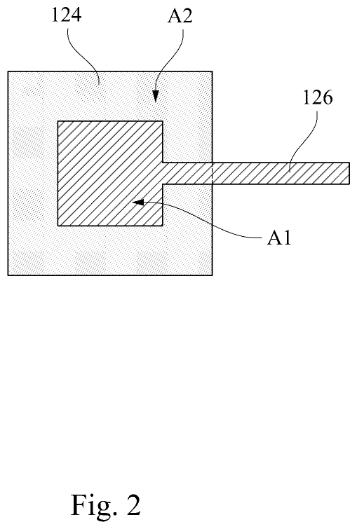

FIG. 2 is a top schematic view of the conductive wire 126 and the second electrode 124 according to various embodiments of the present disclosure. A portion of the conductive wire 126 (the portion to the left of the dotted line) that overlaps the second electrode 124 in top view has a first area A1, the second electrode 124 has a second area A2 in top view, and the first area A1 is smaller than the second area A2. In some embodiments, the transmittance of the second electrode 124 is higher than the transmittance of the conductive wire 126.

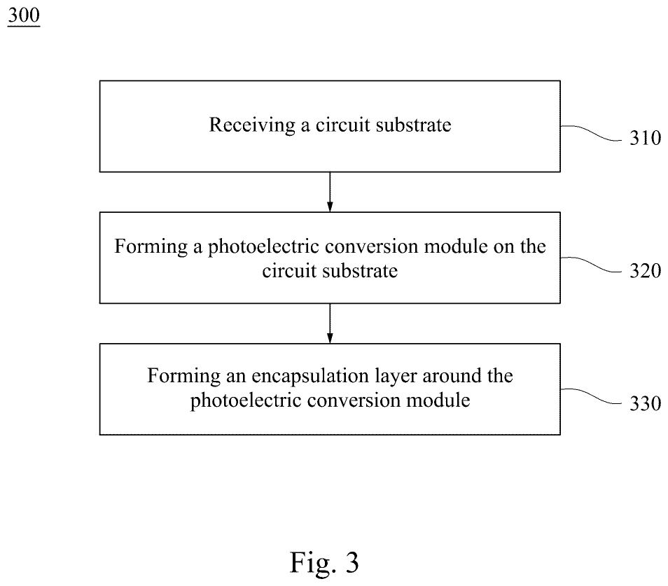

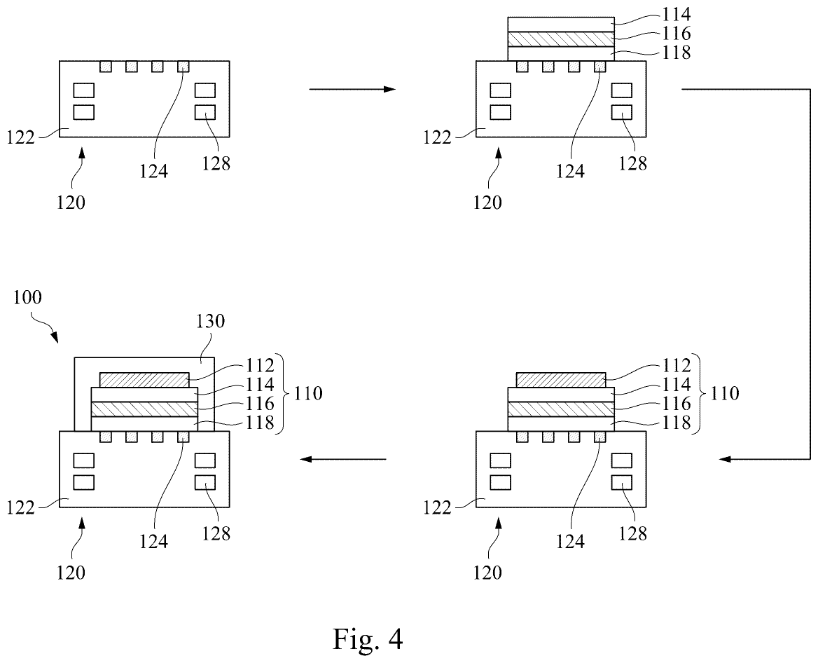

Please refer to FIG. 3 and FIG. 4 at the same time. FIG. 3 is a flowchart of a manufacturing method of the photoelectric device module 100 according to various embodiments of the present disclosure. The method 300 includes operation 310, operation 320, and operation 330. FIG. 4 shows a cross-sectional schematic view of intermediate stages of manufacturing the photoelectric device module 100 according to various embodiments of the present disclosure.

In operation 310, the circuit module 120 is received as shown in FIG. 4. For simplifying the drawing, the conductive wire 126 in the circuit module 120 is not shown in FIG. 4. In operation 320, the photoelectric conversion module 110 is formed on the circuit module 120 as shown in FIG. 4. In more detail, the second carrier transport layer 118 is formed on the circuit module 120, and the photoactive layer 116 is formed on the second carrier transport layer 118. The first carrier transport layer 114 is formed on the photoactive layer 116. The first electrode 112 is formed on the first carrier transport layer 114 to form the photoelectric conversion module 110. In operation 330, the encapsulation layer 130 is formed around the photoelectric conversion module 110 as shown in FIG. 4. In more detail, the encapsulation layer 130 covers the side surface of the photoelectric conversion module 110 and the surface away from the circuit module 120. The photoelectric device module 100 of FIG. 4 is the photoelectric device module 100 of FIG. 1 after being inverted. The photoelectric device module 100′ of FIG. 1B can be manufactured with reference to the process shown in FIG. 4.

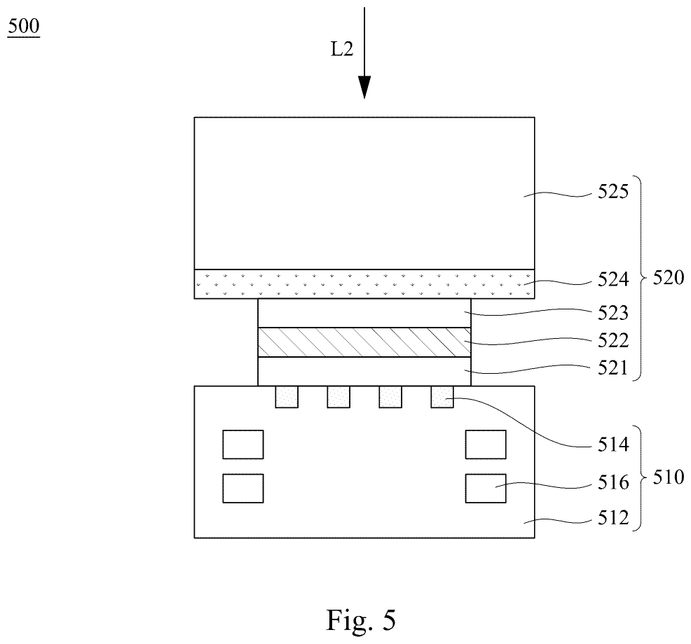

FIG. 5 is a cross-sectional schematic view of a photoelectric device module 500 according to various embodiments of the present disclosure. The present disclosure provides the photoelectric device module 500 that includes a circuit module 510 and a photoelectric conversion module 520 that are bonded with each other. The circuit module 510 includes a first semiconductor substrate 512, a first electrode 514, and a readout circuit 516. The readout circuit 516 may include a thin-film transistor (TFT). Please refer to the embodiments of the circuit module 120 for the embodiments of the circuit module 510, which will not be repeated. The circuit module 510 may further include the conductive wire 126 shown in FIG. 1A; however, for simplifying the drawings, the conductive wire in the circuit module 510 is not shown in FIG. 5. The photoelectric conversion module 520 includes a first carrier transport layer 521, a photoactive layer 522, a second carrier transport layer 523, a second electrode 524, and a second semiconductor substrate 525. The first carrier transport layer 521 is disposed on the circuit module 510, and the photoactive layer 522 is disposed on the first carrier transport layer 521. The second carrier transport layer 523 is disposed on the photoactive layer 522. The second electrode 524 is disposed on the second carrier transport layer 523 and is light-transmissive. The second semiconductor substrate 525 is disposed on the second electrode 524. In some embodiments, the second electrode 524 is referred to as a common electrode.

Please continue to refer to FIG. 5. In some embodiments, the first semiconductor substrate 512 is a silicon substrate, a glass substrate, a polymer substrate, or a ceramic substrate. In some embodiments, the material of the polymer substrate includes polyimide, polyethylene terephthalate, polyethylene naphthalate, polycarbonate, or combinations thereof.

Please continue to refer to FIG. 5. The second semiconductor substrate 525 does not allow visible light to penetrate but allow short-wave infrared (SWIR) light to penetrate. The second semiconductor substrate 525 can be used as a filter for light with a wavelength of less than 1000 nm to filter out unwanted light to prevent interference with the signal detection. In more detail, the second semiconductor substrate 525 has a transmittance of less than 1% for light with a wavelength of less than 1000 nm and a transmittance of more than 10% for light with a wavelength of 1050 nm to 5500 nm. For example, the wavelength is 1050, 1500, 2000, 2500, 3000, 3500, 4000, 4500, or 5000 nm. Accordingly, the photoelectric device module 500 of the present disclosure can respond to SWIR light and be free from visible light interference during detection. The present disclosure provides a method of operating the photoelectric device module 500, which includes receiving light L2 by the photoelectric device module 500, in which the upper surface of the photoelectric device module 500 is a light receiving surface. In other embodiments, the first semiconductor substrate 512 has a transmittance of less than 1% for light with a wavelength of less than 1000 nm and a transmittance of more than 10% for light with a wavelength of 1050 nm to 5500 nm. Accordingly, the lower surface of the photoelectric device module 500 may act as a light receiving surface to receive light from below. In other embodiments, both the upper and lower surfaces of the photoelectric device module 500 are light receiving surfaces. The photoelectric device module 500 can be applied in the field of SWIR sensors. In some embodiments, the photoelectric device module 500 does not have a filter, a filter film, a filter structure, or combinations thereof disposed above the second semiconductor substrate 525.

In the process of manufacturing a general filter, a coating process or an deposition process is usually used to produce a filter, a filter film, or a filter structure; however, the filter, the filter film, or the filter structure usually requires a high-temperature condition and a long process time to be formed, which may damage the components or materials in the photoelectric device module. The second semiconductor substrate 525 of the present disclosure is connected to the lower film by a bonding operation, thus preventing the problem of high-temperature damage mentioned above. As a result, the photoelectric device module 500 of the present disclosure can have good performance and lower manufacturing cost. In addition, the second semiconductor substrate 525 may have better water-blocking and gas-blocking characteristics than a general filter, and thus may be used as part of the packaging structure of the photoelectric device module 500. In some embodiments, the material of the second semiconductor substrate 525 includes silicon. In some embodiments, the second semiconductor substrate 525 is a silicon substrate or a silicon-containing composite substrate. Silicon has a lower cost compared to germanium or indium gallium arsenide, which is advantageous for reducing the manufacturing cost.

The first electrode 514 may be light-transmissive or opaque. For example, the first electrode 514 is opaque and does not allow visible light to penetrate, or the first electrode 514 is transparent and allows visible light to penetrate. In some embodiments, the first electrode 514 is opaque, and the material of the first electrode 514 includes silver, gold, aluminum, copper, molybdenum, titanium, tungsten, titanium nitride, carbon material, or combinations thereof. In some embodiments, the first electrode 514 is light-transmissive, and the first electrode 514 includes a transparent conductive oxide (TCO), a transparent conductive polymer, silver nanowires, a metal-containing layer with a thickness of less than or equal to 15 nm, or combinations thereof. The TCO includes indium zinc oxide (IZO), indium gallium oxide (IGO), indium gallium zinc oxide (IGZO), indium tin oxide (ITO), indium tin zinc oxide (ITZO), aluminum zinc oxide (AZO), or combinations thereof. The transparent conductive polymer includes poly(3,4-ethylenedioxythiophene) polystyrene sulfonate (PEDOT:PSS), polyaniline, ployfluorene, polypyrrole, polythiophene, polycarbazole, or combinations thereof. The metal-containing layer may include a metal layer with a thickness less than or equal to 15 nm, an alloy layer with a thickness less than or equal to 15 nm, or a combination thereof. The metal-containing layer may include silver, gold, aluminum, copper, titanium, molybdenum, titanium nitride, titanium tungsten, or combinations thereof.

The second electrode 524 is light-transmissive. For example, the second electrode 524 is transparent and allows visible light to penetrate. In some embodiments, the second electrode 524 includes a transparent conductive oxide (TCO), a transparent conductive polymer, silver nanowires, a metal-containing layer with a thickness of less than or equal to 15 nm, or combinations thereof. The TCO includes indium zinc oxide (IZO), indium gallium oxide (IGO), indium gallium zinc oxide (IGZO), indium tin oxide (ITO), indium tin zinc oxide (ITZO), aluminum zinc oxide (AZO), or combinations thereof. The transparent conductive polymer includes poly(3,4-ethylenedioxythiophene) polystyrene sulfonate (PEDOT:PSS), polyaniline, ployfluorene, polypyrrole, polythiophene, polycarbazole, or combinations thereof. The metal-containing layer may include a metal layer with a thickness less than or equal to 15 nm, an alloy layer with a thickness less than or equal to 15 nm, or a combination thereof. The metal-containing layer may include silver, gold, aluminum, copper, titanium, molybdenum, titanium nitride, titanium tungsten, or combinations thereof.

Please continue to refer to FIG. 5. Please refer to the embodiments of the first carrier transport layer 114, the photoactive layer 116, and the second carrier transport layer 118 for the embodiments of the first carrier transport layer 521, the photoactive layer 522, and the second carrier transport layer 523, which will not be repeated. In other embodiments, the first carrier transport layer 521 between the circuit module 510 and the photoactive layer 522 is omitted so that the photoactive layer 522 is disposed on the circuit module 510 and directly contacts the circuit module 510, in which the first electrode 514 is disposed between the first semiconductor substrate 512 and the photoactive layer 522. In other embodiments, the second carrier transport layer 523 between the photoactive layer 522 and the second electrode 524 is omitted so that the second electrode 524 is disposed on the photoactive layer 522, the second electrode 524 directly contacts the photoactive layer 522, and the second electrode 524 is disposed between the photoactive layer 522 and the second semiconductor substrate 525.

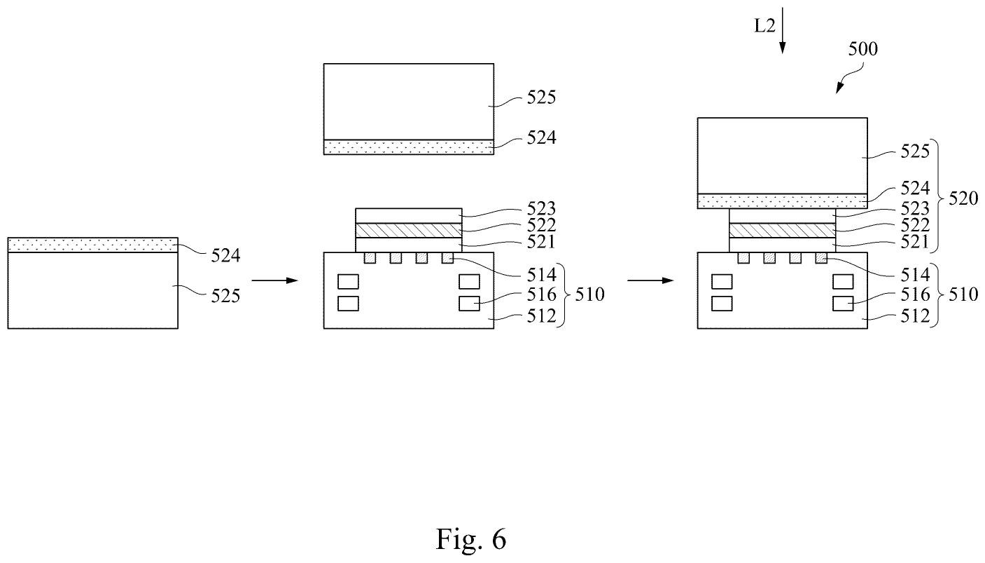

FIG. 6 to FIG. 11 show cross-sectional schematic views of intermediate stages of manufacturing photoelectric devices module according to various embodiments of the present disclosure, respectively.

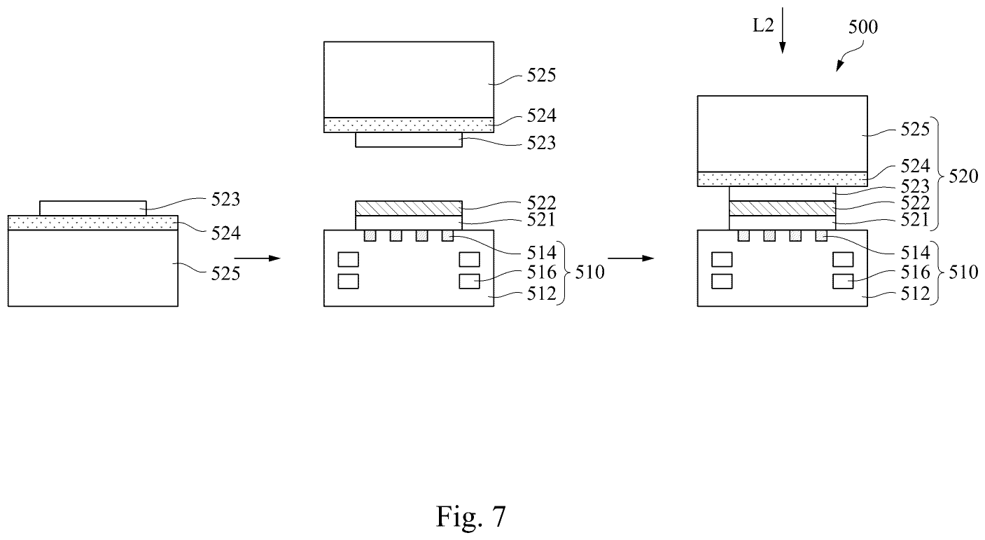

As shown in FIG. 6, a first portion of a photoelectric conversion module 520 is formed. In more detail, a second electrode 524 that is light-transmissive is formed on a second semiconductor substrate 525, thereby forming the first portion of the photoelectric conversion module 520. In some embodiments, when the second electrode 524 includes a transparent conductive oxide, the second electrode 524 is deposited on the second semiconductor substrate 525 by sputtering or electron beam evaporation. In some embodiments, when the second electrode 524 includes a transparent conductive polymer, silver nanowires, a metal-containing layer, or combinations thereof, the second electrode 524 is formed on the second semiconductor substrate 525 by coating or printing. As shown in FIG. 6, a circuit module 510 attached with a second portion of the photoelectric conversion module 520 is formed. In more detail, a first carrier transport layer 521, a photoactive layer 522, and a second carrier transport layer 523 are sequentially formed on the circuit module 510, thereby forming the circuit module 510 attached with the second portion of the photoelectric conversion module 520. Next, the first portion of the photoelectric conversion module 520 and the circuit module 510 attached with the second portion of the photoelectric conversion module 520 are bonded, thereby forming the photoelectric device module 500. In some embodiments, the bonding operation is a physical bonding operation, in which the second carrier transport layer 523 and the second electrode 524 form a Schottky contact. For example, the bonding operation is performed by lamination or adhesion. It is noted that if the light L2 contains light with a wavelength less than 1000 nm, the second semiconductor substrate 525 can be used as a filter to filter this light. Moreover, the second semiconductor substrate 525 may have better water-blocking and gas-blocking characteristics than a general filter, and thus may be used as part of the packaging structure of the photoelectric device module 500. The following photoelectric device modules of FIG. 7 to FIG. 12 also have effects similar to those of the photoelectric device module 500 of FIG. 6, and the effects will not be repeated.

As shown in FIG. 7, a first portion of a photoelectric conversion module 520 is formed. In more detail, a second electrode 524 and a second carrier transport layer 523 are sequentially formed on a second semiconductor substrate 525 to form the first portion of the photoelectric conversion module 520. As shown in FIG. 7, a circuit module 510 attached with a second portion of the photoelectric conversion module 520 is formed. In more detail, a first carrier transport layer 521 and a photoactive layer 522 are sequentially formed on the circuit module 510, thereby forming the circuit module 510 attached with the second portion of the photoelectric conversion module 520. Next, the first portion of the photoelectric conversion module 520 and the circuit module 510 attached with the second portion of the photoelectric conversion module 520 are bonded to form the photoelectric device module 500. In some embodiments, the bonding operation is a physical bonding operation, in which the second carrier transport layer 523 and the photoactive layer 522 form a semiconductor bonding surface. For example, the bonding operation is performed by lamination or adhesion.

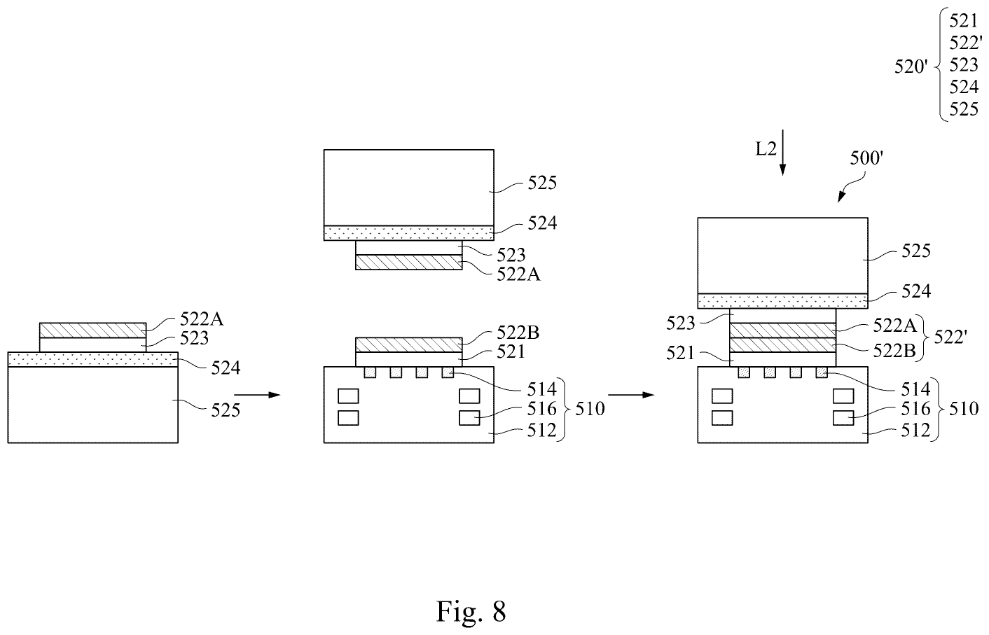

As shown in FIG. 8, a first portion of a photoelectric conversion module 520′ is formed. In more detail, a second electrode 524, a second carrier transport layer 523, and a first photoactive layer 522A are sequentially formed on a second semiconductor substrate 525, thereby forming the first portion of the photoelectric conversion module 520′. As shown in FIG. 8, a circuit module 510 is attached with a second portion of the photoelectric conversion module 520′ is formed. In more detail, a first carrier transport layer 521 and a second photoactive layer 522B are sequentially formed on the circuit module 510 to form the circuit module 510 attached with the second portion of the photoelectric conversion module 520′. Next, the first portion of the photoelectric conversion module 520′ and the circuit module 510 attached with the second portion of the photoelectric conversion module 520′ are bonded to form the photoelectric device module 500′. The difference between the photoelectric device module 500′ and the photoelectric device module 500 is that the photoactive layer 522′ of the photoelectric device module 500′ includes the first photoactive layer 522A and the second photoactive layer 522B that are stacked with each other, and the first photoactive layer 522A and the second photoactive layer 522B are in direct contact with each other to form a bonding interface. Please refer to the embodiments of the photoactive layer 116 for the embodiments of the first photoactive layer 522A and the second photoactive layer 522B, which will not be repeated. In some embodiments, the bonding operation is a physical bonding operation, in which the first photoactive layer 522A and the second photoactive layer 522B form a semiconductor bonding surface. For example, the bonding operation is performed by lamination or adhesion.

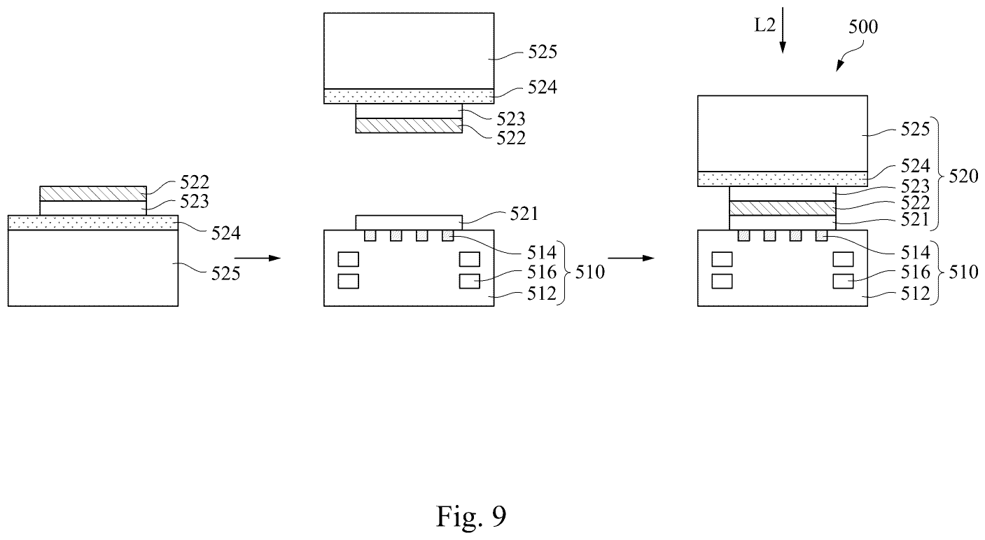

As shown in FIG. 9, a first portion of a photoelectric conversion module 520 is formed. In more detail, a second electrode 524, a second carrier transport layer 523, and a photoactive layer 522 are sequentially formed on a second semiconductor substrate 525, thereby forming the first portion of the photoelectric conversion module 520. As shown in FIG. 9, a circuit module 510 attached with a second portion of the photoelectric conversion module 520 is formed. In more detail, a first carrier transport layer 521 is formed on the circuit module 510, thereby forming the circuit module 510 attached with the second portion of the photoelectric conversion module 520. Next, the first portion of the photoelectric conversion module 520 and the circuit module 510 attached with the second portion of the photoelectric conversion module 520 are bonded to form the photoelectric device module 500. In some embodiments, the bonding operation is a physical bonding operation, in which the photoactive layer 522 and the first carrier transport layer 521 form a semiconductor bonding surface. For example, the bonding operation is performed by lamination or adhesion.

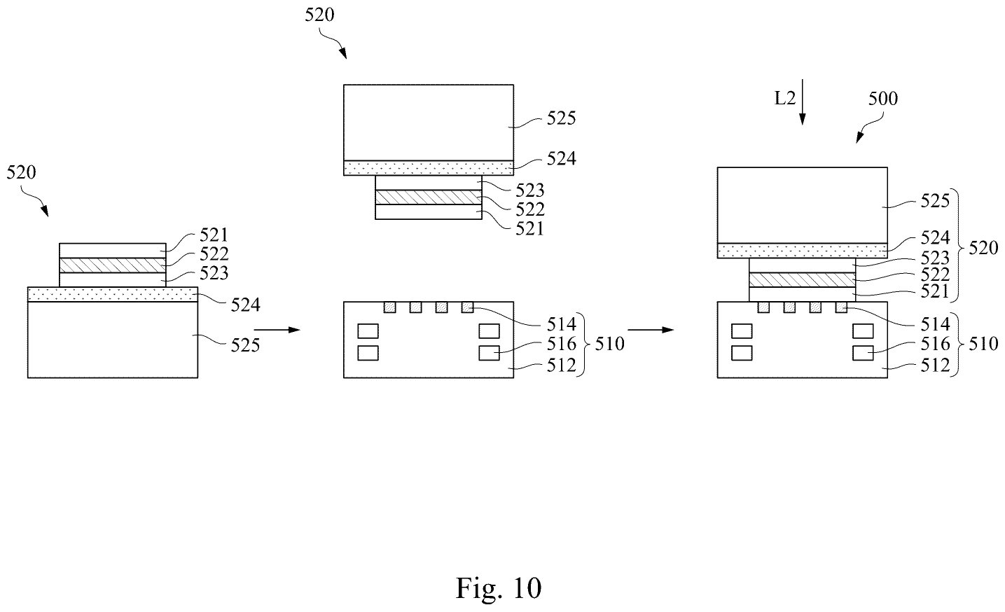

As shown in FIG. 10, a photoelectric conversion module 520 is formed. In more detail, a second electrode 524, a second carrier transport layer 523, a photoactive layer 522, and a first carrier transport layer 521 are sequentially formed on a second semiconductor substrate 525, thereby forming the photoelectric conversion module 520. Next, the photoelectric conversion module 520 and the circuit module 510 are bonded to form the photoelectric device module 500. In some embodiments, the bonding operation is a physical bonding operation, in which the first carrier transport layer 521 and the first electrode form a Schottky contact. For example, the bonding operation is performed by lamination or adhesion.

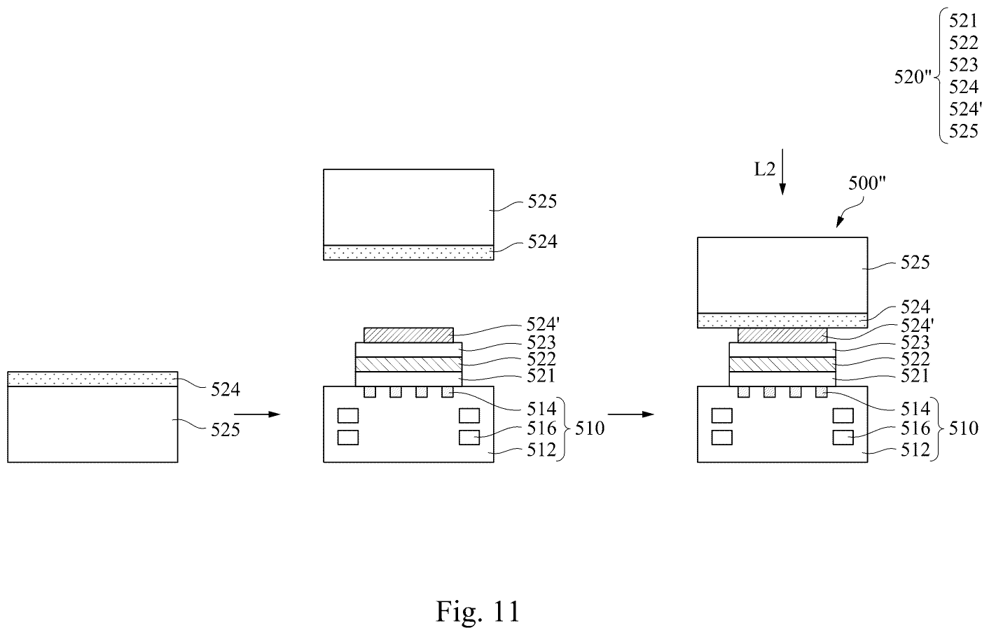

As shown in FIG. 11, a first portion of a photoelectric conversion module 520″ is formed. In more detail, a second electrode 524 is formed on a second semiconductor substrate 525, thereby forming the first portion of the photoelectric conversion module 520″. As shown in FIG. 11, a circuit module 510 attached with a second portion of the photoelectric conversion module 520″ is formed. In more detail, a first carrier transport layer 521, a photoactive layer 522, a second carrier transport layer 523, and a third electrode 524′ are sequentially formed on the circuit module 510, thereby forming the circuit module 510 attached with the second portion of the photoelectric conversion module 520″. Please refer to the material and thickness of the second electrode 524 described above for the material and thickness of the third electrode 524′. Next, the first portion of the photoelectric conversion module 520″ and the circuit module 510 attached with the second portion of the photoelectric conversion module 520″ are bonded to form the photoelectric device module 500″, in which the second electrode 524 and the third electrode 524′ form an Ohmic contact. In some embodiments, the bonding operation is a chemical bonding operation or a physical bonding operation. In some embodiments, the bonding operation is performed by lamination, adhesion, or welding. For example, the welding is solid-state welding (e.g., cold welding). The difference between the photoelectric device module 500″ and the photoelectric device module 500 is that photoelectric device module 500″ further includes the third electrode 524′, in which the third electrode 524′ is disposed between the second carrier transport layer 523 and the second electrode 524. In some embodiments, the second carrier transport layer 523 is omitted, and therefore the third electrode 524′ is disposed between the photoactive layer 522 and the second electrode 524.

The following describes the features of the present disclosure more specifically with reference to Experimental Examples 1 to 2. Although the following examples are described, the materials, their amounts and ratios, processing details, processing procedures, etc., may be appropriately varied without exceeding the scope of the present disclosure. Accordingly, the present disclosure should not be interpreted restrictively by the experimental examples described below.

### Experimental Example 1: Measuring the Properties of Photoelectric Device Modules of Comparative Example 1 and Example 1

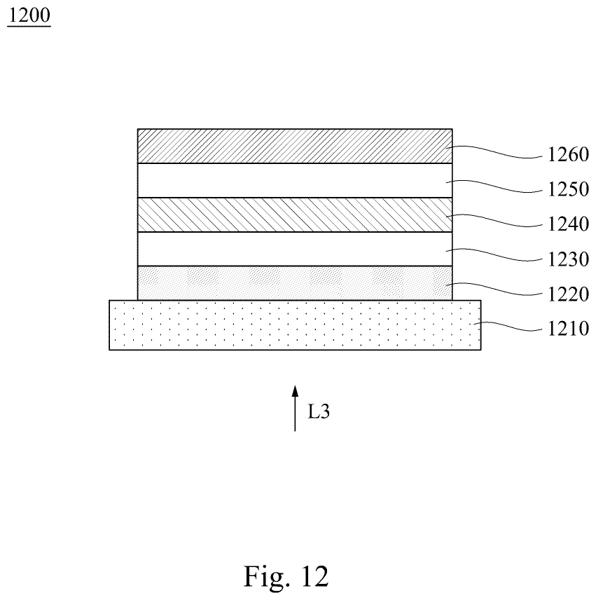

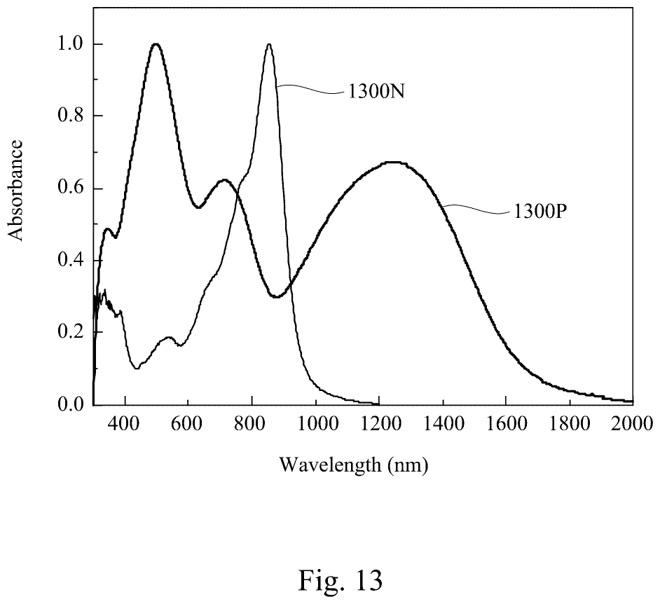

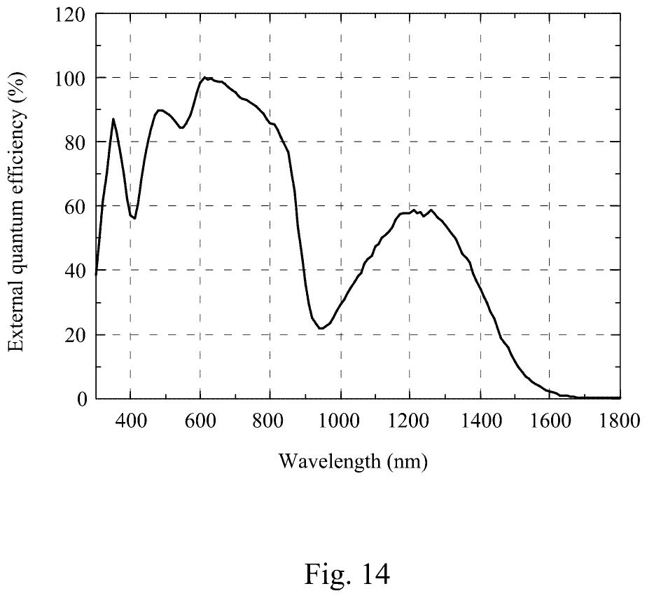

FIG. 12 is a cross-sectional schematic view of a photoelectric device module 1200 of Comparative Example 1. As shown in FIG. 12, the photoelectric device module 1200 includes a glass substrate 1210, an ITO layer 1220 with a thickness of 150 nm, a zinc oxide layer 1230 with a thickness of 40 nm, a photoactive layer 1240 with a thickness of 150 nm, a molybdenum trioxide layer 1250 with a thickness of 10 nm, and a silver electrode 1260 with a thickness of 100 nm. The photoactive layer 1240 includes a P-type organic semiconductor and an N-type organic semiconductor. FIG. 13 shows an absorption spectrum 1300P of the P-type organic semiconductor and an absorption spectrum 1300N of the N-type organic semiconductor. The P-type organic semiconductor has the energy of the highest occupied molecular orbital (HOMO) of −4.91 eV and the energy of the lowest unoccupied molecular orbital (LUMO) of −4.16 eV. The N-type organic semiconductor has the energy of the HOMO of −5.73 eV and the energy of the LUMO of −4.42 eV. Measurements were made by applying light L3 from below, and the measurement results are shown in FIG. 14. FIG. 14 is an external quantum efficiency-wavelength diagram of the photoelectric device module 1200 of Comparative Example 1. As shown in FIG. 14, the photoelectric device module 1200 has high external quantum efficiency in the region where the wavelength is less than 1000 nm, and it can be seen that the glass substrate 1210 cannot filter light with a wavelength less than 1000 nm. In the region where the wavelength is higher than 1000 nm, the external quantum efficiency is lower, which means that the glass substrate 1210 affects the transmittance of light with wavelength higher than 1000 nm.

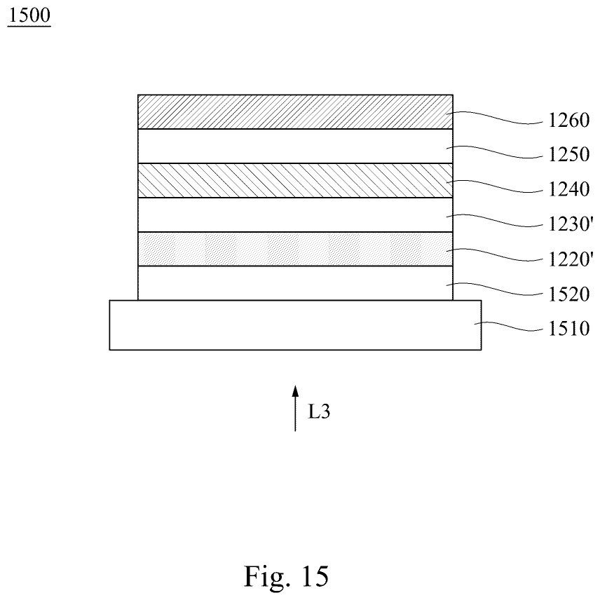

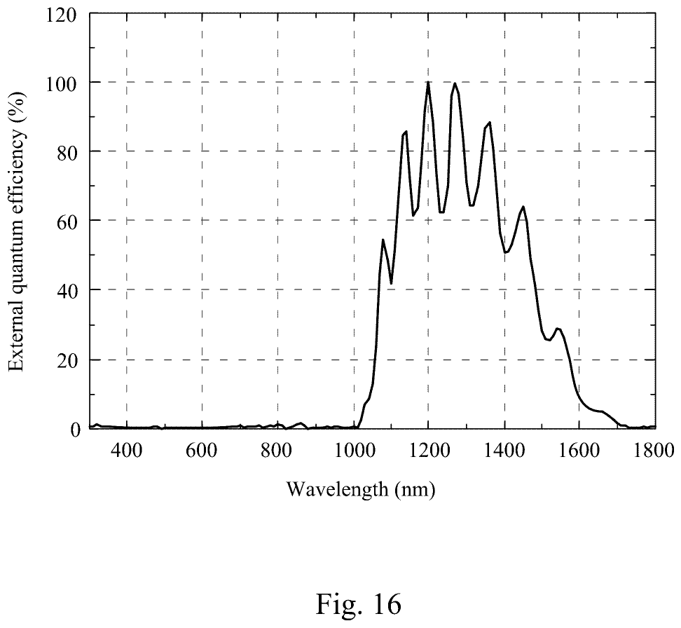

FIG. 15 is a cross-sectional schematic view of a photoelectric device module 1500 of Example 1. The photoelectric device module 1500 includes a silicon substrate 1510, a light-transmissive insulating layer 1520 (trade name: ENPI 200, which contains epoxy resin), an IZO layer 1220′ with a thickness of 150 nm, a zinc oxide layer 1230′ with a thickness of 100 nm, a photoactive layer 1240 with a thickness of 150 nm, a molybdenum trioxide layer 1250 with a thickness of 10 nm, and a silver electrode 1260 with a thickness of 100 nm. Measurements were made by applying light L3 from below, and the measurement results are shown in FIG. 16. FIG. 16 is an external quantum efficiency-wavelength diagram of the photoelectric device module 1500 of Example 1. As shown in FIG. 16, the photoelectric device module 1500 has high external quantum efficiency in the region where the wavelength is higher than 1000 nm. However, in the region where the wavelength is lower than 1000 nm, the photoelectric device module 1500 has almost no external quantum efficiency, and it can be seen that the silicon substrate 1510 is indeed capable of filtering light with a wavelength less than 1000 nm. Therefore, the photoelectric device module 1500 of Example 1 can be used in the field of SWIR sensors.

### Example 2: Measuring the Properties of Photoelectric Device Modules of Comparative Example 2 and Example 2

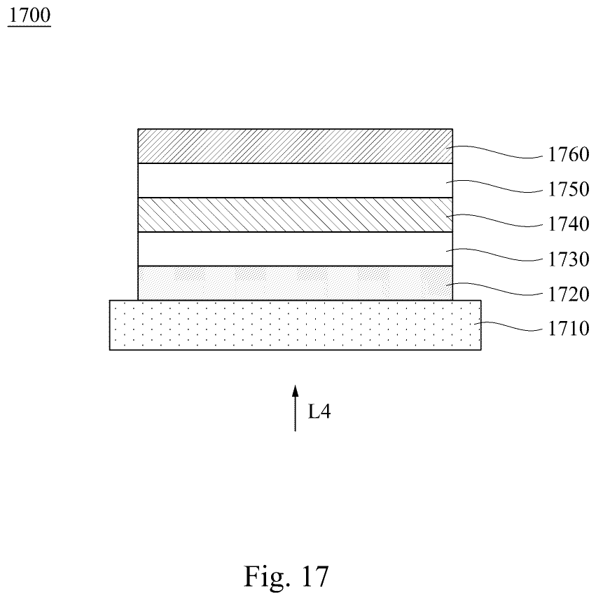

FIG. 17 is a cross-sectional schematic view of a photoelectric device module 1700 of Comparative Example 2. As shown in FIG. 17, the photoelectric device module 1700 includes a glass substrate 1710, an ITO layer 1720 with a thickness of 150 nm, a zinc oxide layer 1730 with a thickness of 40 nm, a photoactive layer 1740 with a thickness of 120 nm, a molybdenum trioxide layer 1750 with a thickness of 10 nm, and a silver electrode 1760 with a thickness of 100 nm. The photoactive layer 1740 includes a P-type organic semiconductor and an N-type organic semiconductor. The P-type organic semiconductor is

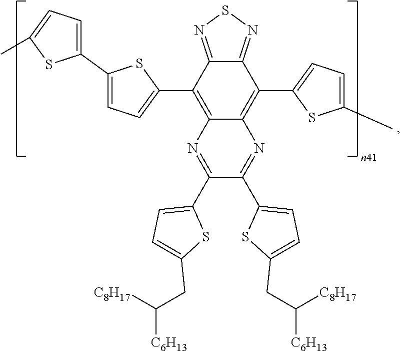

and the N-type organic semiconductor is

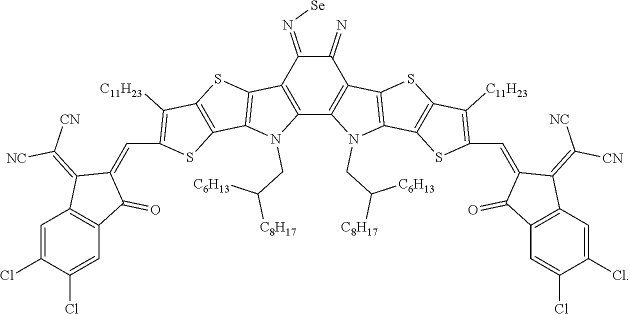

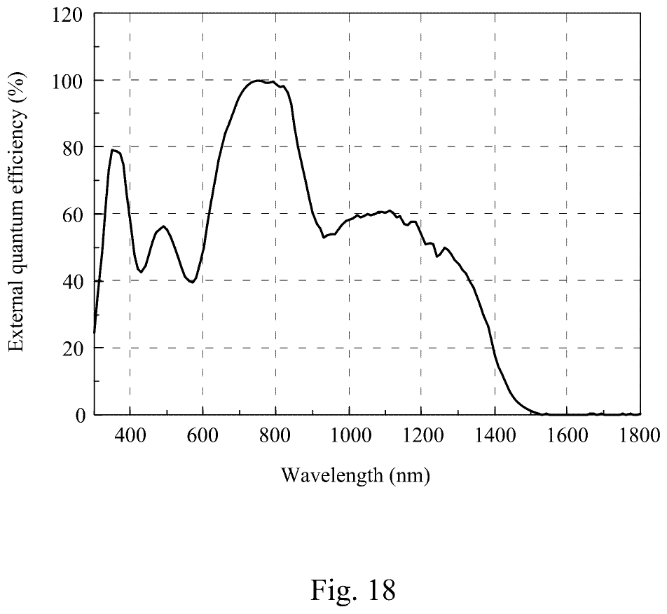

Measurements were made by applying light L4 from below, and the measurement results are shown in FIG. 18. FIG. 18 is an external quantum efficiency-wavelength diagram of the photoelectric device module 1700 of Comparative Example 2. As shown in FIG. 18, the photoelectric device module 1700 has high external quantum efficiency in the region where the wavelength is less than 1000 nm, and it can be seen that the glass substrate 1710 cannot filter light with a wavelength of less than 1000 nm. In the region where the wavelength is higher than 1000 nm, the external quantum efficiency is lower, which means that the glass substrate 1710 affects the transmittance of light L4 with wavelength higher than 1000 nm.

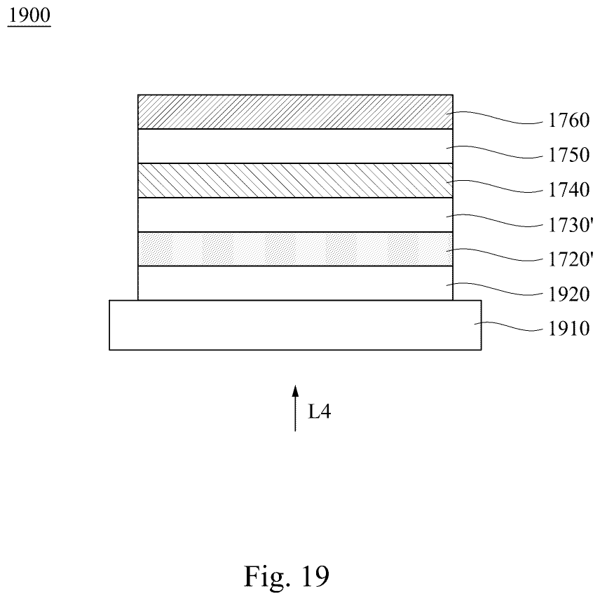

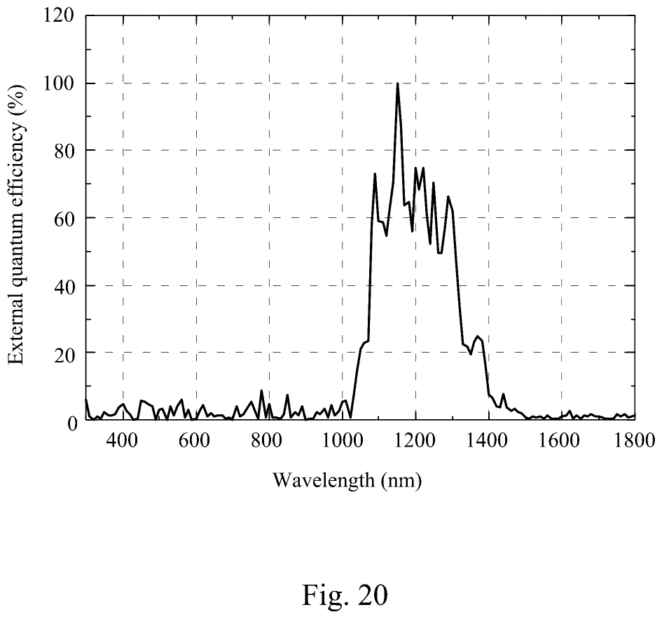

FIG. 19 is a cross-sectional schematic view of a photoelectric device module 1900 of Example 2. The photoelectric device module 1900 includes a silicon substrate 1910, a light-transmissive insulating layer 1920 (trade name: ENPI 200, which contains epoxy resin), an IZO layer 1720′ with a thickness of 150 nm, a zinc oxide layer 1730′ with a thickness of 100 nm, a photoactive layer 1740 with a thickness of 120 nm, a molybdenum trioxide layer 1750 with a thickness of 10 nm, and a silver electrode 1760 with a thickness of 100 nm. Measurements were made by applying light L4 from below, and the measurement results are shown in FIG. 20. FIG. 20 is an external quantum efficiency-wavelength diagram of the photoelectric device module 1900 of Example 2. As shown in FIG. 20, the photoelectric device module 1900 has high external quantum efficiency in the region where the wavelength is higher than 1000 nm. However, in the region where the wavelength is lower than 1000 nm, the photoelectric device module 1900 has almost no external quantum efficiency, and it can be seen that the silicon substrate 1910 is indeed capable of filtering light with a wavelength less than 1000 nm. Therefore, the photoelectric device module 1900 of Example 2 can be used in the field of SWIR sensors.

In summary, the present disclosure provides a photoelectric device module and an operation method thereof. The photoelectric device module includes a semiconductor substrate having a light-filtering function, which does not allow the penetration of visible light, but allows the penetration of short-wave infrared (SWIR) light, thus enabling the photoelectric device module to be used in the field of SWIR sensors and preventing interference with the signal detection. In the photoelectric device module, the semiconductor substrate is connected to another photoelectric conversion module by a bonding operation, and there is no need to dispose other filters in the photoelectric device module, thus preventing the process of manufacturing filters (e.g., deposition process) from affecting the properties of the photoelectric device module. The photoelectric device module of the present disclosure may have excellent photoelectric characteristics, a thin and simple structure, and can reduce manufacturing costs.

Although the present disclosure has been described in considerable detail with reference to certain embodiments, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover the modifications and variations of the present disclosure falling within the scope of the appended claims.

What is claimed is:

1. A photoelectric device module, comprising:
a first electrode, wherein the first electrode is opaque;
a photoactive layer disposed on the first electrode; and
a circuit module disposed on the photoactive layer, wherein the circuit module comprises a semiconductor substrate and a second electrode, the second electrode is disposed between the photoactive layer and the semiconductor substrate, the semiconductor substrate has a transmittance of less than 1% for light having a wavelength of less than 1000 nm and a transmittance of more than 10% for light having a wavelength of 1050 nm to 5500 nm.

2. The photoelectric device module of claim 1, wherein a material of the semiconductor substrate comprises silicon.

3. The photoelectric device module of claim 1, wherein a material of the first electrode comprises silver, gold, aluminum, copper, molybdenum, titanium, tungsten, titanium nitride, carbon material, or combinations thereof.

4. The photoelectric device module of claim 1, further comprising: an encapsulation layer, wherein the encapsulation layer is opaque and covers a side surface and a bottom surface of the first electrode and a side surface of the photoactive layer.

5. The photoelectric device module of claim 1, wherein the second electrode is light-transmissive.

6. The photoelectric device module of claim 1, wherein the circuit module further comprises a conductive wire, the conductive wire is embedded in the semiconductor substrate and is electrically connected to the second electrode, a portion of the conductive wire overlapping the second electrode has a first area in top view, the second electrode has a second area in top view, and the first area is smaller than the second area.

7. The photoelectric device module of claim 1, further comprising:
a first carrier transport layer disposed between the first electrode and the photoactive layer; and
a second carrier transport layer disposed between the photoactive layer and the circuit module.

8. The photoelectric device module of claim 1, wherein the circuit module further comprises a light-transmissive insulating layer, the light-transmissive insulating layer is disposed between the photoactive layer and the semiconductor substrate, and the second electrode is embedded in the light-transmissive insulating layer.

9. A method of operating a photoelectric device module, comprising:
receiving light by the photoelectric device module of claim 1, wherein an upper surface of the circuit module is a light receiving surface.

10. A photoelectric device module, comprising:
a circuit module, wherein the circuit module comprises a first semiconductor substrate and a first electrode;
a photoactive layer disposed on the circuit module, wherein the first electrode is disposed between the first semiconductor substrate and the photoactive layer;
a second electrode disposed on the photoactive layer, wherein the second electrode is light-transmissive; and
a second semiconductor substrate disposed on the second electrode, wherein the second semiconductor substrate has a transmittance of less than 1% for light having a wavelength of less than 1000 nm and a transmittance of more than 10% for light having a wavelength of 1050 nm to 5500 nm.

11. The photoelectric device module of claim 10, wherein the photoactive layer comprises a first photoactive layer and a second photoactive layer that are stacked, and the first photoactive layer and the second photoactive layer are in direct contact with each other to form a bonding interface.

12. The photoelectric device module of claim 10, further comprising: a third electrode, wherein the third electrode is disposed between the photoactive layer and the second electrode.

13. The photoelectric device module of claim 10, further comprising:
a first carrier transport layer disposed between the circuit module and the photoactive layer; and
a second carrier transport layer disposed between the photoactive layer and the second electrode.

14. The photoelectric device module of claim 10, wherein a material of the second semiconductor substrate comprises silicon.

15. The photoelectric device module of claim 10, wherein the second electrode comprises a transparent conductive oxide, a transparent conductive polymer, silver nanowires, a metal-containing layer with a thickness of less than or equal to 15 nm, or combinations thereof.

16. A method of operating a photoelectric device module, comprising:
receiving light by the photoelectric device module of claim 12, wherein the photoelectric device module has a light receiving surface, and the light receiving surface is an upper surface, a lower surface, or a combination of the photoelectric device module.
